(19) United States
(12) Patent Application Publication
(10) Pub. No.: US 2022/0277691 A1
(43) Pub. Date: Sep. 1, 2022

(54) DISPLAY PANEL AND DISPLAY DEVICE

(71) Applicant: Wuhan Tianma Microelectronics Co., Ltd, Wuhan (CN)

(72) Inventors: Meihong WANG, Wuhan (CN); Yangzhao MA, Wuhan (CN); Lilian KUANG, Wuhan (CN)

(73) Assignee: Wuhan Tianma Microelectronics Co., Ltd., Wuhan (CN)

(21) Appl. No.: 17/719,558

(22) Filed: Apr. 13, 2022

(30) Foreign Application Priority Data
Apr. 22, 2021 (CN) 202110437276.6

(51) Int. Cl. G09G 3/3208; H01L 27/32

(52) U.S. Cl. CPC G09G 3/3208; H01L 27/3276; G09G 2300/0842; G09G 2310/061; G09G 2320/0214; H01L 27/3272

(57) ABSTRACT

Provided are a display panel and a display device. The display panel includes pixel driving circuits disposed in array, first signal lines, shielding unit, and base substrate. The pixel driving circuits electrically connected to the first signal lines. The pixel driving circuits, the first signal lines, and the shielding unit disposed on side of the base substrate. Along direction perpendicular to a plane the base substrate located, at least part of the pixel driving circuits overlap the shielding unit. The first signal line includes first line segment. The first line segment is at least part of the shielding unit. The display panel and the display device have high resolution and meet requirements of light transmission and display of a high light-transmitting region in display panel.

### CROSS-REFERENCE TO RELATED APPLICATION(S)

This application claims priority to Chinese Patent Application No. 202110437276.6 filed Apr. 22, 2021, titled “DISPLAY PANEL AND DISPLAY DEVICE”, the disclosure of which is incorporated herein by reference in its entirety.

### FIELD

Embodiments of the present disclosure relate to the field of display technologies and, in particular, to a display panel and a display device.

### BACKGROUND

An organic light-emitting diode (OLED) display has become one of the most popular displays currently with the advantages including self-luminescence, low drive voltage, high luminous efficiency, short response time, and flexible display.

Since an OLED element of the OLED display is a current-driven element, a corresponding pixel driving circuit is needed to be provided to supply a drive current to the OLED element and drive the OLED element to emit light. Additionally, a corresponding signal line is disposed in an OLED display device to transmit a corresponding signal to the pixel driving circuit and control the pixel driving circuit to drive the OLED element to emit light. In the related art, pixel driving circuits with the function of threshold compensation are usually disposed in the display panel to solve the problem of threshold voltage bias of driving transistors in the pixel driving circuits caused by processing and device aging.

However, currently, the pixel driving circuits with the function of threshold compensation require an arrangement of various signals lines so as to supply corresponding signals to the pixel driving circuits, resulting in relatively large size of both the pixel driving circuits and the signal lines electrically connected to the pixel driving circuits, going against a high PPI (pixels per inch) of a display panel, and failing to meet the requirements of light transmission and display in a high light-transmitting region of the display panel.

### SUMMARY

According to the preceding problems, embodiments of the present disclosure provide a display panel and a display device to reduce an area occupied by both pixel driving circuits and signal lines connected to the pixel driving circuits, contribute to a high resolution of a display panel, and meet requirements of light transmission and display in a high transmission region of the display panel.

In a first aspect, embodiments of the present disclosure provide a display panel. The display panel includes a plurality of pixel driving circuits disposed in an array, a plurality of first signal lines, a shielding unit, and a base substrate.

The pixel driving circuits are electrically connected to the first signal lines.

The pixel driving circuits, the first signal lines, and the shielding unit are all disposed on a side of the base substrate. Along a direction perpendicular to the plane in which the base substrate is located, at least part of the pixel driving circuits overlap the shielding unit.

The first signal line includes a first line segment, and the first line segment is at least part of the shielding unit.

In a second aspect, embodiments of the present disclosure further provide a display device. The display device includes the preceding display panel.

### BRIEF DESCRIPTION OF DRAWINGS

FIG. 1 is a structure diagram illustrating of a display panel in the related art.

FIG. 2 is a circuit structure diagram of a pixel driving circuit in the related art.

FIG. 3 is a top view illustrating part of a display panel in the related art.

FIG. 4 is a top view illustrating part of a display panel according to an embodiment of the present disclosure.

FIG. 5 is a section view taken along section A-A of FIG. 4.

FIG. 6 is a top view illustrating part of a display panel according to another embodiment of the present disclosure.

FIG. 7 is a top view of a display panel according to an embodiment of the present disclosure.

FIG. 8 is a structure diagram illustrating a layer structure of a display panel according to another embodiment of the present disclosure.

FIG. 9 is a top view illustrating part of a display panel according to another embodiment of the present disclosure.

FIG. 10 is a section view taken along section B-B of FIG. 9.

FIG. 11 is a structure diagram illustrating the film layer structure of a display panel according to another embodiment of the present disclosure.

FIG. 12 is a top view illustrating part of a display panel according to another embodiment of the present disclosure.

FIG. 13 is a top view illustrating part of a display panel according to another embodiment of the present disclosure.

FIG. 14 is a section view taken along section C-C of FIG. 13.

FIG. 15 is a structure diagram illustrating a layer structure of a display panel according to another embodiment of the present disclosure.

FIG. 16 is a top view illustrating part of a display panel according to another embodiment of the present disclosure.

FIG. 17 is a section view taken along section D-D of FIG. 16.

FIG. 18 is a top view illustrating part of a display panel according to another embodiment of the present disclosure.

FIG. 19 is a section view taken along section E-E of FIG. 18.

FIG. 20 is a structure diagram illustrating a layer structure of a display panel according to another embodiment of the present disclosure.

FIG. 21 is a top view illustrating part of a display panel according to another embodiment of the present disclosure.

FIG. 22 is a section view taken along section F-F of FIG. 21.

FIG. 23 is a top view illustrating part of a display panel according to another embodiment of the present disclosure.

FIG. 24 is a top view illustrating part of a display panel according to another embodiment of the present disclosure.

FIG. 25 is a section view taken along section J-J of FIG. 24.

FIG. 26 is a top view illustrating part of a display panel according to another embodiment of the present disclosure.

FIG. 27 is a section view taken along section I-I of FIG. 26.

FIG. 28 is a top view illustrating part of a display panel according to another embodiment of the present disclosure.

FIG. 29 is a top view illustrating part of a display panel according to another embodiment of the present disclosure.

FIG. 30 is a section view taken along section K-K of FIG. 29.

FIG. 31 is a top view illustrating part of a display panel according to another embodiment of the present disclosure.

FIG. 32 is a section view taken along section L-L of FIG. 31.

FIG. 33 is a top view illustrating part of a display panel according to another embodiment of the present disclosure.

FIG. 34 is a top view illustrating part of a display panel according to another embodiment of the present disclosure.

FIG. 35 is a structure diagram illustrating a display panel according to an embodiment of the present disclosure.

FIG. 36 is a top view illustrating part of a display panel according to another embodiment of the present disclosure.

FIG. 37 is a structure diagram illustrating a display device according to an embodiment of the present disclosure.

FIG. 38 is a section view taken along section M-M of FIG. 37.

### DETAILED DESCRIPTION

The present disclosure is further described hereinafter in detail in conjunction with drawings and embodiments. It is to be understood that embodiments described hereinafter are intended to explain the present disclosure and not to limit the present disclosure. Additionally, it is to be noted that for ease of description, only part, not all, of structures related to the present disclosure are illustrated in the drawings.

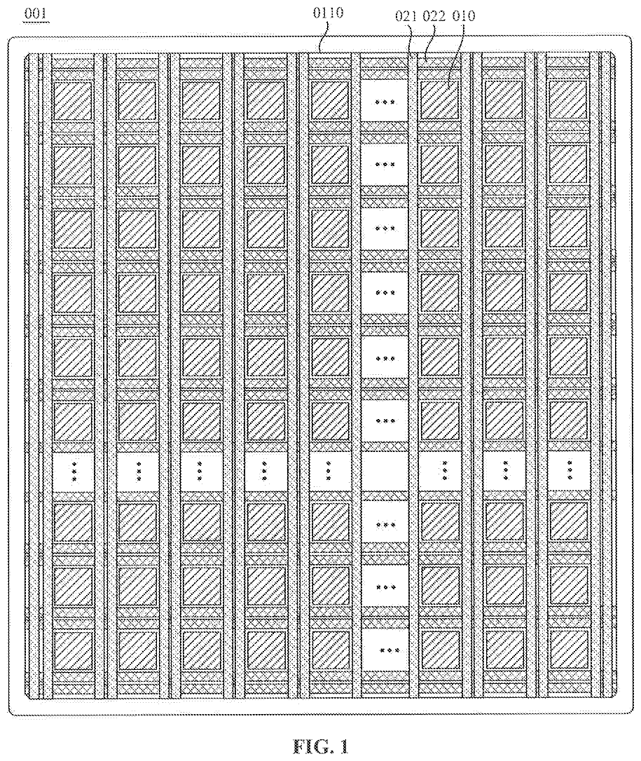

FIG. 1 is a structure diagram illustrating a display panel in the related art. As shown in FIG. 1, a display region 0110 of a display panel 001 includes a plurality of pixel driving circuits 010 and a plurality of signal lines 021 and 022 intersecting with each other. The signal lines 021 and 021 define the positions of the pixel driving circuits 010 and transmit corresponding signals to the pixel driving circuits so that the pixel driving circuits 010 drive light-emitting elements to emit lights (not shown).

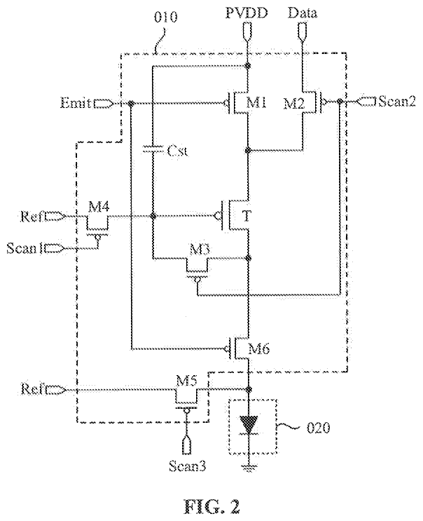

In the related art, pixel driving circuits with the function of threshold compensation are usually disposed in the display panel to solve the problem of threshold voltage bias of driving transistors in the pixel driving circuits caused by processing and device aging. A conventional pixel driving circuit with the function of threshold compensation is a 7T1C pixel driving circuit. FIG. 2 is a circuit structure diagram of a pixel driving circuit in the related art. As shown in FIGS. 1 and 2, a pixel driving circuit 010 includes seven transistors and one storage capacitor Cst. The seven transistors are a driving transistor T, an initialization transistor M4, a data writing transistor M2, a threshold compensation transistor M3, a reset transistor M5, a first light-emitting control transistor M1, and a second light-emitting control transistor M6 respectively. In this case, various scanning signal lines (a first scanning signal line Scan1, a second scanning signal line Scan2, a third scanning signal line Scan3, and a light-emitting control signal line Emit) are needed to set in the display panel 001 for electrical connection to the gate of each of the seven transistors in the pixel driving circuit, to control each transistor to be turned on or to be turned off separately. Moreover, a plurality of signal lines electrically connected to the sources or drains of each transistor are also disposed in the display panel 001, for example, a data signal line Data for transmitting a data signal, a reset signal line Ref for transmitting an initialization signal and a reset signal, and a power supply signal line PVDD for transmitting a power supply signal. In this manner, in the initialization phase, the first scanning signal transmitted by the first scanning signal line Scanl controls the initialization transistor M4 to be turned on. In this case, the initialization signal transmitted by the reset signal line Ref are written into the gate of the driving transistor T and the storage capacitor Cst through the initialization transistor M4 turned on to initialize the gate of the driving transistor T and the storage capacitor Cst, thus facilitating other signals to be written. In the data writing phase, the second scanning signals transmitted by the second scanning signal line Scan2 control the data writing transistor M2 and the threshold compensation transistor M3 to be turned on. In this case, the data signals transmitted by the data signal line Data are written into the gate of the driving transistor T and the storage capacitor Cst sequentially through the data writing transistor M2, the driving transistor T, and the threshold compensation transistor M3 that have been turned on. Moreover, the threshold voltage of the driving transistor T is compensated. In the resetting phase, the third scanning signal transmitted by the third scanning signal line Scan3 controls the reset transistor M5 to be turned on. In this case, the reset signals transmitted by the reset signal line Ref are written to the anode of a light-emitting element 020 through the reset transistor M5 to reset the anode of the light-emitting element 020. In the light-emitting phase, the light-emitting control signals transmitted by the light-emitting control signal line Emit control the first light-emitting control transistor M1 and the second light-emitting control transistor M6 to be turned on. In this case, the drive current provided by the driving transistor T flows into the light-emitting element 020 to drive the light-emitting element 020 to emit light. Since the threshold voltage of the driving transistor T is compensated in the data writing phase, the drive current provided by the driving transistor T for the light-emitting element 020 in the light-emitting phase is unrelated to the threshold voltage of the driving transistor T, thus ensuring the light-emitting element 020 to emit light accurately and stably and enhancing the display effect of the display panel 001.

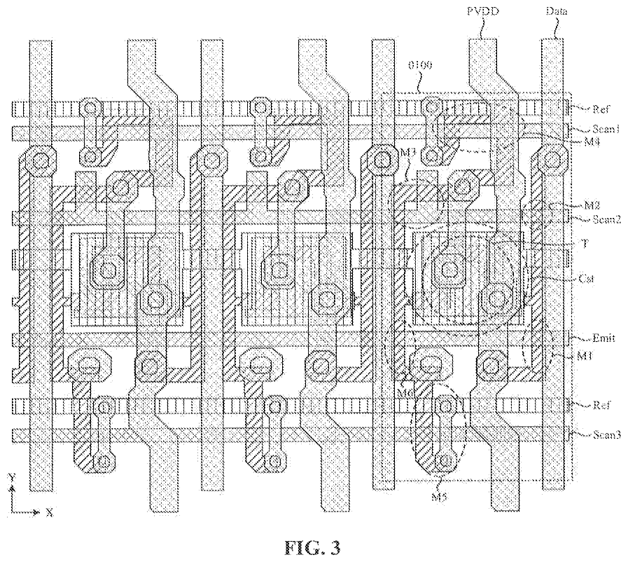

However, different signal lines are required to be disposed in the display panel to provide corresponding signals for the 7T1C pixel driving circuits with the function of threshold compensation. Accordingly, the area occupied by the driving units formed by the pixel driving circuits and the lines electrically connected to the pixel driving circuits are relatively large. FIG. 3 is a top view illustrating part of a display panel in the related art. As shown in FIG. 3, each driving unit 0100 (including a pixel driving circuit and the signal lines electrically connected to the pixel driving circuit) has a relatively large size either in the horizontal direction X or in the longitudinal direction Y, thus going against the high PPI of the display panel and failing to meet the requirements of light transmission and display in a high light-transmitting region.

To solve the preceding technical problems, embodiments of the present disclosure provide a display panel. The display panel includes a plurality of pixel driving circuits disposed in an array, a plurality of first signal lines, a shielding unit, and a base substrate. The pixel driving circuits are electrically connected to the first signal lines. The pixel driving circuits, the first signal lines, and the shielding unit are all disposed on a side of the base substrate. Along a direction perpendicular to the plane in which the base substrate is located, at least part of the pixel driving circuits overlap the shielding unit. The first signal line includes a first line segment, and the first line segment is at least part of the shielding unit.

With adoption of the preceding technical solutions, in a first aspect, the arrangement of the shielding unit overlapping at least part of the pixel driving circuits and part of the first signal lines shields an external electric field and/or optical signals from affecting the pixel driving circuits or other elements disposed in the display panel, thus enhancing the performance of the display panel, which may be, for example, display performance. In a second aspect, the arrangement in which a first line segment of a first signal line being at least part of a shielding unit enables the first line segment to transmit corresponding signals to a pixel driving circuit and implement the function of shielding external electric field and/or optical signals, thus simplifying the design of the display panel. In a third aspect, when a first line segment is at least part of the shielding unit, the place originally used for disposing the first line segment is vacated to reduce the area of regions for placing the pixel driving circuit and the signal line electrically connected to the pixel driving circuit, thus increasing the number of the pixel driving circuits disposed in a unit area of the display panel and enhancing the resolution of the display panel. Moreover, when the area of regions for placing the pixel driving circuit and the signal line is reduced, the area of regions not for placing pixel driving circuit or signal line in the display panel are increased, thus increasing the light-transmitting area of the display panel and meeting the requirements of light transmission and display in a high light-transmitting region.

The preceding is the core idea of the present disclosure. Based on embodiments of the present disclosure, all other embodiments obtained by those skilled in the art without creative work are within the scope of the present disclosure. Technical solutions in embodiments of the present disclosure are described clearly and completely hereinafter in conjunction with the drawings in embodiments of the present disclosure.

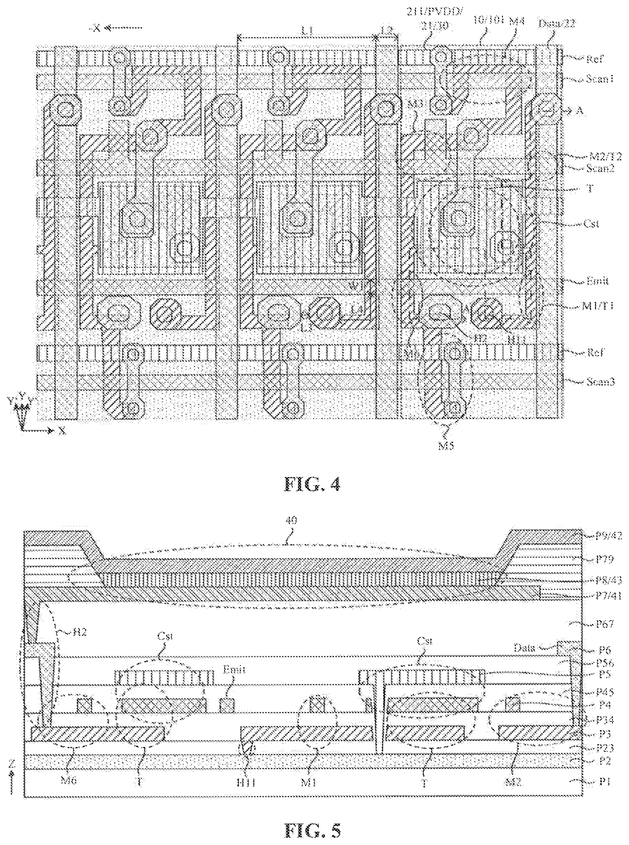

FIG. 4 is a top view illustrating part of a display panel according to an embodiment of the present disclosure. FIG. 5 is a section view taken along section A-A of FIG. 4. Referring to

FIGS. 4 and 5, the display panel includes a base substrate P1, a plurality of light-emitting elements 40 disposed in an array, a plurality of pixel driving circuits 10 disposed in an array, and a plurality of first signal lines 21. The light-emitting elements 40, the pixel driving circuits 10, and the first signal lines 21 are disposed on a side of the base substrate P1. The pixel driving circuit 10 is electrically connected to the first signal line 21. The first signal line 21 can transmit corresponding signals to the pixel driving circuit 10 and control the pixel driving circuit 10 to drive the light-emitting element 40 to emit light.

A shielding unit 30 is disposed on a side of the base substrate P1. Along a direction Z perpendicular to the plane in which the base substrate P1 is located, at least part of the pixel driving circuits 10 overlap the shielding unit 30. The overlapping herein means that in a plane, both a region where at least part of the pixel driving circuits 10 are located and a region where at least part of the first signal lines 21 are located overlap a region where the shielding unit 30 is located. Any structure inside the overlapping region may further serve as another structure inside the overlapping region. The shielding unit 30 may be configured to shield an external electric field and/or external optical signals. For example, when the shielding unit 30 are configured to shield an external electric field, the shielding unit 30 can shield the electric field generated on the side of the base substrate P1 to prevent the electric field from affecting the performance of the pixel driving circuits 10 or the performance of some elements in the pixel driving circuits 10 and to prevent the electric field from affecting the stability of signals transmitted by the first signal lines 21. When the shielding unit 30 are configured to shield external optical signals, the shielding unit 30 may prevent that external light signals affect channels of transistors in the pixel driving circuits 10, and further cause threshold drifts of the transistors in the pixel driving circuits 10 and affect the display effect. Alternatively, the shielding unit 30 may work as light-blocking structures that can improve the imaging accuracy of an optical sensor (not shown). In this manner, the arrangement of the shielding unit 30 disposed in the display panel can enhance the display effect of the display panel and/or improve the imaging accuracy of an optical sensing element in the display panel.

Correspondingly, under the premise of not affect other structural designs in the display panel, the shielding unit 30 may be made of one or more layers. It is to be understood that a first conductive layer for disposing the shielding unit may be located between any one or any combination of the base substrate and the pixel driving circuits, functional film layers in the pixel driving circuits, the pixel driving circuits and the light-emitting elements, and may be designed based on actual needs in practical applications. As shown in FIG. 5, this embodiment is described for illustration by merely taking the first conductive layer P2 for disposing the shielding unit 30 disposed between the pixel driving circuits 10 and the base substrate P1 as an example.

With further reference to FIGS. 4 and 5, the first conductive layer P2 for disposing the shielding unit 30 may be made of materials with conductive function. In this case, along a direction Z perpendicular to the plane in which the base substrate P1 is located, a first signal line 21 may include a first line segment 211. The first line segment 211 is at least part of the shielding unit 30. In this manner, the arrangement in which the first line segment 211 is disposed in the first conductive layer P2 can vacate places in other functional film layers (P3 to P9) which are originally used for disposing the first line segment 211, thus reducing the area of regions for placing the pixel driving circuits 10 and the first signal lines 21 electrically connected to the pixel driving circuits 10. Accordingly, the number of pixel driving circuits disposed in a unit area of the display panel is increased and the resolution of the display panel is enhanced. Moreover, when the area of regions for placing the pixel driving circuits and the signal lines is reduced, the area of regions not for placing the pixel driving circuits or the signal lines in the display panel are increased, thus increasing the light-transmitting area of the display panel and meeting the requirements of light transmission and display in a high light-transmitting region in the display panel.

It is to be understood that the functional film layers (P3 to P9) described herein do not refer to a single layer, but a combination of a plurality of film layers for forming structures such as the pixel driving circuits, the signal lines, and the light-emitting elements and the like in the display panel.

It is to be noted that the structures of the currently known pixel driving circuits are various. The signal lines for controlling the operation of the pixel driving circuits may be designed based on actual needs. That is, the first signal lines electrically connected to the pixel driving circuits may be any signal lines that can transmit signals to the pixel driving circuits and are not specifically limited in embodiments of the present disclosure. Moreover, for ease of description, embodiments of the present disclosure are described for example only with an example in which the pixel driving circuits are 7T1C pixel driving circuits. Embodiments of the present disclosure are also applicable to other pixel driving circuits increasing or decreasing active elements and/or passive elements on the basis of the 7T1C pixel driving circuits. The active elements include a transistor and the like. The passive elements include a capacitor, a resistor, an inductor, and the like.

The current 7T1C pixel driving circuits usually include seven transistors and one storage capacitor. The first signal lines electrically connected to the 7T1C pixel driving circuits may be signal lines electrically connected to the sources or drains of the transistors in the 7T1C pixel driving circuits or may be signal lines electrically connected to the gates of the transistors in the 7T1C pixel driving circuits. The effect of different types of signal lines as the first signal lines on the pixel driving circuits and on other signal lines are described for example hereinafter.

In an embodiment, when the first signal line is a signal line electrically connected to a source or a drain of a transistor in a pixel driving circuit, with further reference to FIGS. 4 and 5, the pixel driving circuit 10 includes at least one first transistor T1. The pixel driving circuit 10 electrically connected to a first line segment 211 of a first signal line 21 refers to a first-type pixel driving circuit 101. The first pole of a first transistor T1 in the first-type pixel driving circuit 101 is electrically connected to the first line segment 211 through a first via hole H11.

In embodiments of the present disclosure, in a case where the first pole is a source, the second pole is a drain; or, in a case where the first pole is a drain, the second pole is a source. That is, when the transistor is a P-type transistor, the first pole is the source and the second pole is the drain, so that signals transmitted by the first signal line are input from the source of the first transistor and output from the drain of the first transistor T1. When the transistor is an N-type transistor, the first pole is the drain and the second pole is the source, so that signals transmitted by the first signal line are output from the drain of the first transistor and output from the source of the transistor.

In this manner, the arrangement in which the first line segment 211 is at least part of the shielding unit 30 and electrically connected to the first pole of a first transistor T1 in the first-type driving circuit 101 vacates the places originally used for disposing the first line segment 211, thus reducing the area of regions for placing the pixel driving circuits 10 and the first signal lines 21 electrically connected to the pixel driving circuits 10. Accordingly, the number of pixel driving circuits disposed in a unit area of the display panel is increased and the resolution of the display panel is enhanced. Moreover, when the area of regions for placing the pixel driving circuits and the signal lines is reduced, the area of regions not for placing the pixel driving circuits or the signal lines in the display panel are increased, thus increasing the light-transmitting area of the display panel and meeting the requirements of light transmission and display in a high light-transmitting region in the display panel.

In an embodiment, with further reference to FIGS. 4 and 5, the display panel further includes a plurality of second signal lines 22. The pixel driving circuit 10 further includes a second transistor T2. The first pole of the second transistor T2 is electrically connected to a second signal line 22. Moreover, second transistors T2 in at least part of the pixel driving circuits 10 disposed in a same column share a second signal line 22. Along the row direction X of the pixel driving circuits, the distance between two second signal lines 22 electrically connected to two adjacent first-type pixel driving circuits 101 in the same row respectively is L1. The width of a second signal line 22 is L2. L1 and L2 satisfies 6≤L1/L2≤8.

Specifically, in the related art, signal lines with the same extension direction are disposed in a same layer. In this technical solution, the first line segments 211 of the first signal lines 21 in a same extension direction as a second signal line 22 are disposed in the first conductive layer P2 for disposing the shielding unit 30. Accordingly, compared with the related art, the area of regions where signal lines in the third metal layer P6 in which the second signal lines 22 are disposed is reduced, vacating the places originally used for disposing the first line segment 211 in the third metal layer P6 in which the second signal lines 22 are disposed. In this case, a partial structure of the first-type pixel driving circuit 101 and the second signal lines 22 are movable such that a distance between two second signal lines 22 electrically connected to two adjacent first-type pixel driving circuits 101 respectively is shortened. That is, under the premise that the width of the second signal line 22 is unchanged, the ratio of the distance between two second signal lines 22 electrically connected to two adjacent first-type pixel driving circuits 101 respectively to the width of a second signal line 22 is shortened. Accordingly, along the row direction X of the pixel driving circuits 10, the total size of a first-type pixel driving circuit 101 and a second signal line 22 electrically connected to the first-type pixel driving circuit 101 may be reduced by 4% to 14%; that is, the area of the region where the first-type pixel driving circuits 101 are located may be reduced by 4% to 14%. With this arrangement, compared with the related art, an area of the region where the first-type pixel driving circuit 101 is located in the display panel is reduced, thus increasing the number of the pixel driving circuits 10 disposed in the display panel and enhancing the resolution of the display panel. Moreover, when the area of the region where the first-type pixel driving circuit 101 is located is reduced, the area of regions where no pixel driving circuit or no signal line is located in the display panel is increased, thus increasing the light-transmitting area of the display panel and meeting the requirements of light transmission and display in a high light-transmitting region.

In an embodiment, with further reference to FIGS. 4 and 5, each light-emitting element 40 in the display panel is usually electrically connected to each pixel driving circuit 10 so that each light-emitting element 40 is driven by the corresponding pixel driving circuit 10 to emit light. Correspondingly, at least one first transistor T1 may include a first light-emitting control transistor M1. The pixel driving circuit 10 may further include a second light-emitting control transistor M6 and a driving transistor T. The second pole of the first light-emitting control transistor M1 is electrically connected to the first pole of the driving transistor T. The first pole of the second light-emitting control transistor M6 is electrically connected to the second pole of the driving transistor T. The second pole of the second light-emitting control transistor M6 is electrically connected to the anode 41 of a light-emitting element 40 through a second via hole H2. In this case, along a first direction Y′, the first via hole H11 electrically connected to the first light-emitting control transistor M1 overlaps the second via hole H2. The first direction Y′ is parallel to the plane in which the base substrate P1 is located. A first included angle is disposed between the first direction Y′ and the column direction Y of the pixel driving circuits 10.

For example, the first line segment 211 of a first signal line 21 is disposed in the first conductive layer P2 where the shielding unit 30 is disposed. Accordingly, compared with the related art, the place originally used for disposing the first line segment 211 is vacated, such that partial structure of the first-type pixel driving circuit 10 is movable along the direction −X. That is, the first light-emitting control transistor M1, as well as other structures electrically connected to the first light-emitting control transistor M1 directly, move towards the second light-emitting control transistor M6, which leads to that the distance L3 between the second via hole H2 electrically connecting the second light-emitting control transistor M6 to the light-emitting element 40 and the first via hole H11 electrically connecting the first light-emitting control transistor M1 to the first line segment 211 is relatively small. Accordingly, along the direction Y′ having a relatively small deviation angle (the first included angle) against the column direction Y of the pixel driving circuits 10, the first via hole H11 overlaps the second via hole H2. The first included angle may be a relatively small angle, for example, smaller than or equal to 10 degrees. In this case, the first direction Y′ is approximately parallel to the column direction Y of the pixel driving circuits 10.

When the first signal line 21 is a signal line electrically connected to the first pole of the first light-emitting control transistor M1, the first signal line 21 is a positive power voltage signal line PVDD for transmitting a positive power voltage signal to the first pole of the first light-emitting control transistor M1. Correspondingly, the second signal line 22 may be a data signal line Data. The second transistor T2 electrically connected to the data signal line Data may be a data writing transistor M2.

It is to be noted that FIG. 4 is only an exemplary drawing of embodiments of the present disclosure. FIG. 4 merely illustrates that the distance between the first via hole H11 and the second via hole H2 is shortened by moving partial structure of the first-type pixel driving circuit 101 by way of example. In embodiments of the present disclosure, when a first line segment is at least part of a shielding unit, there may be other implementations reducing the area of the region where the first-type pixel driving circuits 101 are located.

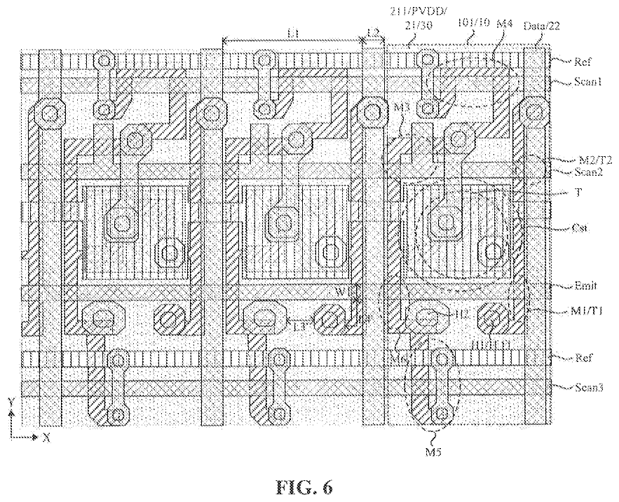

For example, FIG. 6 is a top view illustrating part of a display panel according to another embodiment of the present disclosure. For similarities between FIG. 6 and FIG. 4, refer to the preceding description of FIG. 4. Only the differences between FIG. 6 and FIG. 4 are for example described herein. Referring to FIGS. 4 and 6, after the place originally used for disposing the first line segment 211 is vacated, the first light-emitting control transistor M1, as well as at least part of other structures electrically connected to the first light-emitting control transistor M1 directly, move towards the second light-emitting control transistor M6, and the position of the first via hole H11 electrically connected to the first light-emitting control transistor M1 may be unchanged. In this case, compared with the related art, the horizontal distance between the first via hole H11 and the position where a channel region of the first light-emitting control transistor M1 is located is shortened from L4 to L4′. That is, under the premise that the width W1 of the channel region of the first light-emitting control transistor M1 is unchanged, the ratio of the non-channel region of the first light-emitting control transistor M1 to the channel region of the first light-emitting control transistor M1 may be reduced; that is, L4′/W1<L4/W1. In this manner, the size of the first-type pixel driving circuit 101 along the row direction X of the pixel driving circuits 10 is reduced.

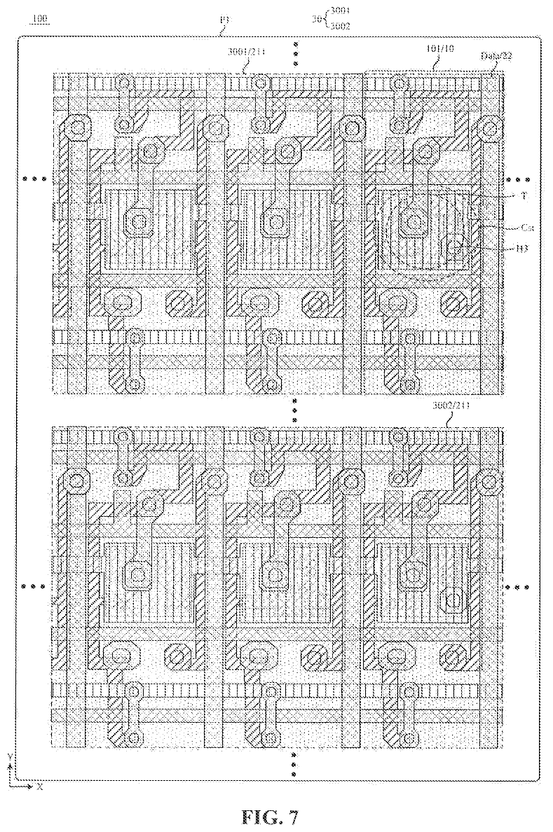

In an embodiment, FIG. 7 is a top view of a display panel according to an embodiment of the present disclosure. As shown in FIG. 7, the shielding unit 30 of the display panel 100 include a plurality of shielding sub-units (3001 and 3002). Along a direction perpendicular to the plane in which the base substrate P1 is located, each shielding sub-unit (3001 or 3002) overlaps N pixel driving circuits 10. The pixel driving circuit 10 further includes a storage capacitor Cst. The first plates of the storage capacitors Cst in the N pixel driving circuits 10 overlapping the same shielding sub-unit (3001 or 3002) are an integral structure. Among the first-type pixel driving circuits 101, the first plates of the storage capacitors Cst being the integral structure are electrically connected to a same first line segment 211 through M third via holes H3. M<N. M and N are both positive integers.

Specifically, in a pixel driving circuit 10, the first plate of the storage capacitor Cst is usually electrically connected to a fixed voltage signal, and the second plate of the storage capacitor Cst is electrically connected to the gate of the driving transistor T, so that the storage capacitor Cst stores the gate potential of the driving transistor T stably. To reduce the number of signal lines in the display panel 100, the positive power voltage signal line electrically connected to the first pole of the first light-emission control transistor M1 may also serve as a signal line electrically connected to the first plate of the storage capacitor Cst. In this case, the storage capacitor Cst and the first light-emission control transistor that belong to a same pixel driving circuit 10 may be electrically connected to a same positive power voltage signal line PVDD. Moreover, since the positive power voltage signals transmitted by the positive power voltage signal line PVDD are fixed voltage signals, the performance of each pixel driving circuit 10 may not be affected even if different pixel driving circuits 10 share a positive power voltage signal line PVDD. In this case, the first plate of the storage capacitor Cst in each pixel driving circuit 10 overlapping the same shielding sub-unit (3001 or 3002) may be electrically connected to the same shielding sub-unit (3001 or 3002). Moreover, the number of third via holes H3 electrically connecting a shielding sub-unit (3001 or 3002) to first plates of storage capacitors Cst in the first-type pixel driving circuits 101 may be smaller than the number of the first-type pixel driving circuits 101 overlapping the shielding sub-unit (3001 or 3002), saving the space for disposing the third via holes H3 and thus further reducing the total area of regions where pixel driving circuits overlapping the same shielding sub-unit (3001 or 3002) is located.

It is to be understood that when the shielding unit 30 include a plurality of shielding sub-units (3001 or 3002), each shielding sub-unit (3001 or 3002) overlaps at least one pixel driving circuit. This arrangement may be understood that each shielding sub-unit overlaps partial structure of at least one pixel driving circuit. Alternatively, this arrangement may be understood that along the direction perpendicular to the plane in which the base substrate P1 is located, each shielding sub-unit (3001 or 3002) overlaps at least one pixel driving circuit 10. That is, each shielding sub-unit (3001 or 3002) may overlap one, two, or more pixel driving circuits 10. In this case, each shielding sub-unit may perform the shielding function to at least one pixel driving circuit 10. The number of pixel driving circuits 10 overlapped by each shielding sub-unit (3001 or 3002) is not limited in embodiments of this disclosure. Moreover, any two shielding sub-units may be independent of each other. Alternatively, any two shielding sub-units may overlap each other or may also be served as each other, which is not limited in embodiments of the present disclosure.

For example, as shown in FIG. 7, each shielding sub-unit 3001 (3002) may overlap three pixel driving circuits 10. The three pixel driving circuits 10 may be pixel driving circuits 10 for driving three light-emitting elements of different colors in a same pixel unit.

It is to be understood that referring to FIGS. 4, 5, and 7, when a first signal line 21 is a positive power voltage signal line PVDD, the signals transmitted by the first signal line are fixed voltage signals. In this case, each shielding sub-unit (3001 or 3002) may include at least one first shielding structure. The first conductive layer P2 disposed on a side of the base substrate P1 may include the at least one first shielding structure. The first line segment 211 is the first shielding structure. The first line segments 211 electrically connected to pixel driving circuits 100 covered by the same shielding sub-unit (3001 or 3002) is an integral structure. In this manner, each shielding sub-unit (3001, 3002) may perform a good shielding function to each pixel driving circuit 10 only by disposing the shielding unit 30 in the first conductive layer P2. Moreover, since the first line segment 211 electrically connected to pixel driving circuits 100 overlapped by the same shielding sub-unit (3001 or 3002) is an integral structure, the first line segment 211 has a relatively large cross-sectional area, thus reducing the resistance of the first line segment 211, decreasing losses of the signals transmitted on the first line segment 211, and further enhancing the display effect of the display panel.

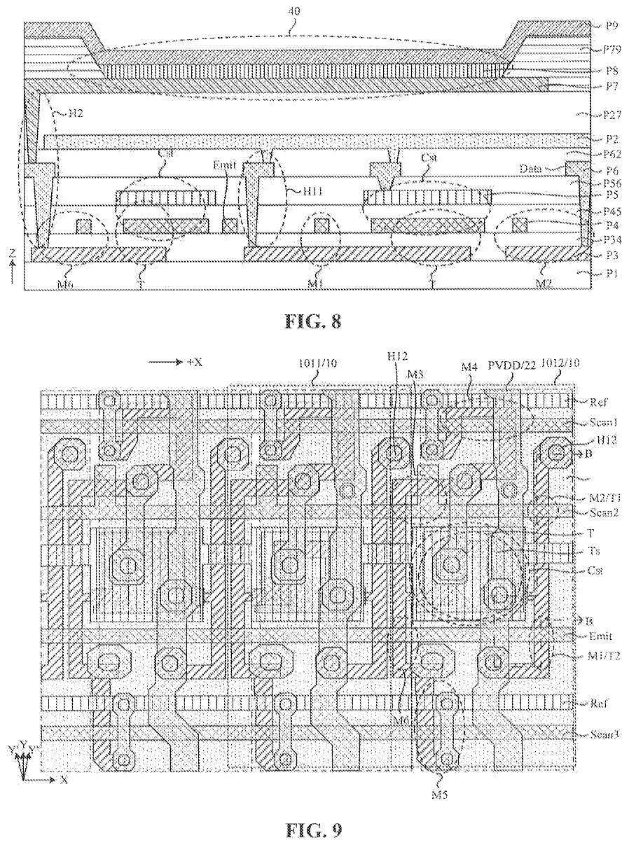

It is to be noted that as shown in FIG. 5, in embodiments of the present disclosure, the first conductive layer P2 also serving as the shielding unit of first line segments may be disposed between the base substrate P1 and a semiconductor layer P3 in which active layers of transistors in the pixel driving circuits are located. Alternatively, as shown in FIG. 8, the first conductive layer P2 also serving as the shielding unit of first line segments may be disposed between the light-emitting elements 40 and the third metal layer P6 where the second signal line (Data) is located. In this case, to facilitate the design of the first via hole H11, a corresponding lap joint structure may be disposed in the third metal layer P6 in which the second signal line is disposed. Alternatively, the first conductive layer also serving as the shielding unit of first line segments may be disposed between other functional film layers and is not specifically limited in embodiments of the present disclosure.

It is to be understood that as shown in FIG. 5, the display panel may further include a first metal layer P4 for disposing the gate of the driving transistor T, a second metal layer P5 for disposing the first plate of the storage capacitor Cst, an anode metal layer P7 for disposing anodes 41 of the light-emitting elements 40, a light-emitting layer P8 for disposing light-emitting layers 43 of the light-emitting elements 40, and a cathode layer P9 for disposing cathodes 42 of the light-emitting elements 40. Additionally, the display panel may further include insulating layers disposed between two adjacent functional film layers, for example, an insulating layer P23 disposed between the first conductive layer P2 and the semiconductor layer P3, an insulating film layer P34 disposed between the semiconductor layer P3 and the first metal layer P4, an insulating layer P45 disposed between the first metal layer P4 and the second metal layer P5, an insulating layer P56 disposed between the second metal layer P5 and the third metal layer P6, a planarization film layer P67 disposed between the third metal layer P6 and the anode metal layer P7, and the pixel defining layer P79 for defining the positions of the light-emitting elements 40. Alternatively, when the first conductive layer P2 also serving as the shielding unit of first line segments is disposed between the light-emitting elements 40 and the third metal layer P6 in which the second signal line (Data) is disposed, different from FIG. 5 and as shown in FIG. 8, an insulating film layer P62 is disposed between the third metal layer P6 and the first conductive layer P2; and a planarization layer P27 is disposed between the first conductive layer P2 and the anode metal layer P7.

It is to be noted that FIGS. 5 and 8 only illustrate the relative positional relationship between film layers by way of example. In embodiments of the present disclosure, the relative positional relationship between film layers may be interchanged on the basis of meeting the requirements of the design. After layers are interchanged, corresponding insulating layers may be disposed based on actual needs. Only functional film layers involved in embodiments of the present disclosure are illustrated for example hereinafter. Those skilled in the art can conceive that an insulating layer needs to be disposed between any two functional film layers. The manner for disposing an insulating layer is not repeated hereinafter.

It is to be understood that the preceding is an exemplary description of embodiments of the present disclosure with an example in which a first signal line is a positive power voltage signal line. When the first signal line is a signal line electrically connected to the source or the drain of a first transistor in a pixel driving circuit, the first signal line may also be a data signal line.

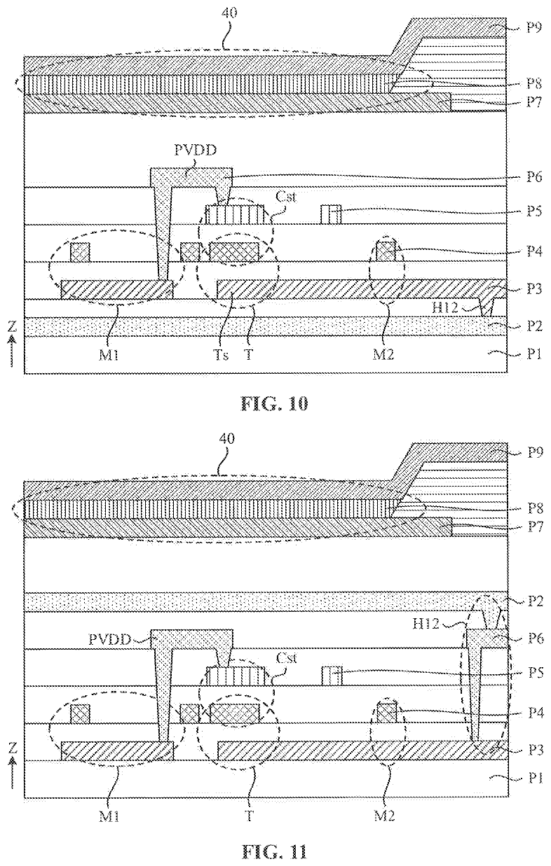

In an embodiment, FIG. 9 is a top view illustrating part of a display panel according to another embodiment of the present disclosure. FIG. 10 is a section view taken along section B-B of FIG 9. Referring to FIGS. 9 and 10, when the first signal line 21 is a data signal line Data, the second signal line 22 may be a positive power voltage signal line PVDD. In this case, when at least part of the shielding unit 30 further serves as the data signal line Data electrically connected to the first-type pixel driving circuits (1011, 1012), compared with the related art, the place originally used for disposing the data signal line Data electrically connected to the first-type pixel driving circuits (1011, 1012) is vacated in the third metal layer P6 where the second signal line 22 (PVDD) is located, so that the first-type pixel driving circuit 1011 (or 1012) and the second signal line PVDD electrically connected to the first-type pixel driving circuit are movable along the direction +X. Accordingly, the distance between two adjacent signal lines PVDD is shortened, a shorten magnitude thereof is up to the width of the original data signal line Data. When the width of positive power voltage signal line PVDD in the related art is the same as or similar to the width of the data signal line Data, the ratio of the distance L1 between two adjacent second signal lines PVDD electrically connected to first-type pixel driving circuits (1011 and 1012) respectively to the width of a second signal line PVDD may also be that 6≤L1/L2≤8.

In an embodiment, with further reference to FIGS. 9 and 10, when the first signal line 21 is the data signal line Data, at least one first transistor T may include a data writing transistor M2. The pixel driving circuit 10 may further include a driving transistor T. The data writing transistor M2 is configured to write the data signal transmitted by the data signal line Data into the gate of the driving transistor T. In this case, two adjacent first-type pixel driving circuits disposed sequentially along the row direction X of the pixel driving circuits are a first pixel driving circuit 1011 and a second pixel driving circuit 1012 respectively. The first via hole H13 electrically connected to the data writing transistor M2 of the first pixel driving circuit 1011 overlaps an active layer Ts of the driving transistor T of the second pixel driving circuit 1012 along the first direction Y′. The first direction Y′ is parallel to the plane in which the base substrate P1 is located. A first included angle is disposed between the first direction Y′ and the column direction Y of the pixel driving circuits 10.

Specifically, at least part of the shielding unit 30 further serves as the data signal line Data electrically connected to a first-type pixel driving circuit. That is, the data signal line Data is disposed in the first conductive layer P1 to vacate the place originally used for disposing the data signal line Data in the third metal layer P6, thus shortening the distance between two adjacent first-type pixel driving circuits (1011, 1012). Moreover, as the distance between two adjacent first-type pixel driving circuits (1011 and 1012) is shortened, the distance between elements in the two adjacent first-type pixel driving circuits (1011 and 1012) is shortened till regions where the two adjacent first-type pixel driving circuits (1011 and 1012) are located overlap each other. In this case, along the first direction Y′, the first via hole H13 electrically connected to the data writing transistor M2 of the first pixel driving circuit 1011 overlaps the active layer Ts of the driving transistor T of the second pixel driving circuit 1012. The active layer T2 specifically refers to a region where the active layer T of the driving transistor overlaps the gate of the driving transistor along a direction perpendicular to the plane in which the base substrate P1 is located, for example, the region of the active layer of the driving transistor T, where the region of the active layer is in shape of the Chinese character “n”. Moreover, the pixel driving circuit 10 usually further includes a storage capacitor Cst electrically connected to the gate of the driving transistor T. The storage capacitor Cst is configured to store the gate potential of the driving transistor T. One plate (the second plate) of the storage capacitor Cst may also serve as the gate of the driving transistor T such that along the first direction, the first via hole H13 electrically connected to the data writing transistor M2 in the first pixel driving circuit 1011 may also overlap the storage capacitor Cst. In this manner, the arrangement in which data signal lines Data electrically connected to the first-type pixel driving circuits (1011, 1012) are disposed in the first conductive layer P2 reduces the area of regions where the first-type pixel driving circuits (1011, 1012) and the signal lines electrically connected to the first-type pixel driving circuits (1011, 1012) are located, thus enhancing the resolution of the display panel and meeting the requirements of light transmission and display of high transmission rate.

The first direction Y′ is a direction having a relatively small included angle (the first included angle) with the column direction Y of the pixel driving circuits 10. The first included angle only needs to meet the following requirement: after at least part of the shielding unit 30 further serves as the data signal line Data, two adjacent pixel driving circuits overlap each other so that the total area of regions where several adjacent pixel driving circuits are located is reduced. For example, the first direction Y′ is approximately parallel to the column direction Y of the pixel driving circuits 10.

It is to be noted that FIG. 10 is only an exemplary drawing of embodiments of the present disclosure. FIG. 10 only illustrates that the first conductive layer P2 where the shielding unit 30 also serving as the data signal line Data is located is disposed between the base substrate P1 and the film layer P3 where the active layer T of the driving transistor T is located, by way of example. In embodiments of the present disclosure, as shown in FIG. 11, the first conductive layer P2 where the shielding unit 30 is located also serving as the data signal line Data may be further disposed between the film layer P6 where the second signal line (the positive power voltage signal line PVDD) is located and the light-emitting elements 40. In this case, to facilitate the design of the first via hole H12, structures in the film layer P6 may be utilized to form an lap joint structure. Alternatively, the film layer where the shielding unit is located also serving as the data signal line may be disposed based on actual conditions, which is not limited in embodiments of the present disclosure.

It is to be understood that with further reference to FIGS. 9 and 10, when the first signal line 21 is a data signal line Data, the signals transmitted by the first signal line are variable voltage signals. In this case, any two first shielding structures also serving as first line segments 211 in the first conductive layer P1 are insulated from each other to avoid signal crosstalk.

Correspondingly, any two adjacent first line segments 211 in the first conductive layer P1 are insulated from each other so that a gap may exist between any two adjacent first line segments in the first conductive layer P1. In this case, to prevent the gap from affecting the shielding effect of the shielding unit 30, other shielding structures may be disposed in the film layers to fill the gap between any two adjacent first line segments.

For example, with further reference to FIGS. 9 and 10, when a gap exists between any two adjacent first line segments 211 in the first conductive layer P2, a third shielding structure may be disposed in the anode metal layer P7 where the anodes of the light-emitting elements 40 are disposed and the third shielding structure is configured to fill the gap between the two adjacent first line segments 211 to enhance the shielding effect of the shielding unit 30.

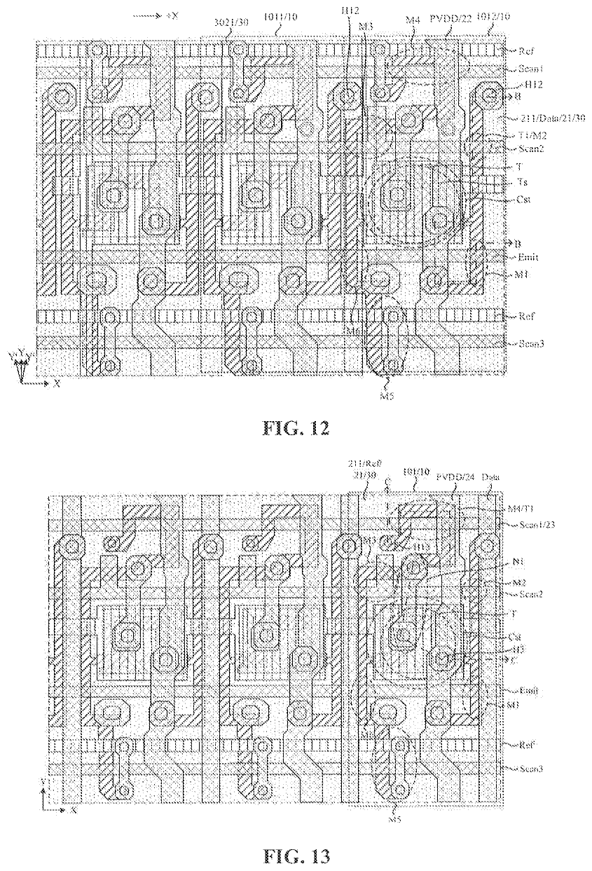

For example, FIG. 12 is a top view illustrating part of a display panel according to another embodiment of the present disclosure. Referring to FIGS. 10 and 12, the pixel driving circuit 10 usually further includes a storage capacitor Cst. The first plate of the storage capacitor Cst is usually disposed in the second metal layer P5. Additionally, the second metal layer P5 may further include a second shielding structure 3021 of the shielding unit 30. Along a direction Z perpendicular to the plane in which the base substrate P1 is located, the second shielding structure 3021 overlaps a gap among the at least one first shielding structure 211 disposed in the first conductive layer P2. In this manner, the shielding unit 30 are guaranteed to perform the shielding function to every position of the pixel driving circuits 10.

It is to be noted that the first shielding structures disposed in the second metal layer P5 and the third shielding structures disposed in the anode metal layer may be both or either provided. This is not specifically limited in embodiments of the present disclosure.

It is to be understood that the preceding is an exemplary description with an example in which a first signal line is a signal line extending along the column direction of the pixel driving circuits. When the first signal line is a signal line electrically connected to the source or the drain of a first transistor in a pixel driving circuit, the first signal line may further be a signal line extending along the row direction of the pixel driving circuits.

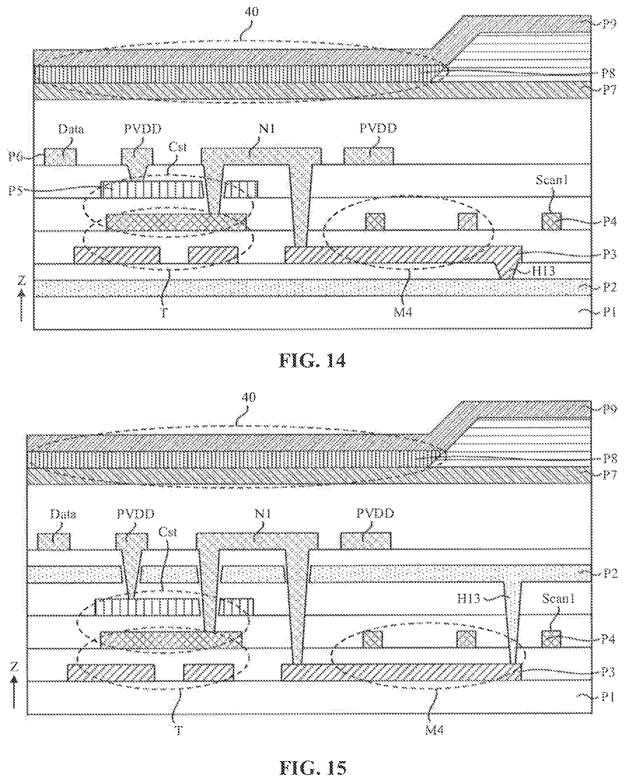

In an embodiment, FIG. 13 is a top view illustrating part of a display panel according to another embodiment of the present disclosure. FIG. 14 is a section view taken along section C-C of FIG. 13. Referring to FIGS. 13 and 14, the display panel further includes the semiconductor layer P3 disposed on a side of the base substrate P1 and the first metal layer P4 disposed on a side of the semiconductor layer P3 facing away from the base substrate P1. The semiconductor layer P3 includes the active layer of the first transistor T1. The first metal layer P4 includes a plurality of third signal lines 23. Along a direction perpendicular to the plane in which the base substrate P1 is located, the position where a third signal line 21 overlaps the active layer of the first transistor T1 is the gate of the first transistor T1. First transistors T1 in at least part of the pixel driving circuits 10 disposed in a same row share a third signal line 23 and a first signal line 21.

Specifically, since at least part of the pixel driving circuits 10 in the same row share a first signal line 21, the first signal line 21 extends along the row direction of the pixel driving circuits 10. When the first line segment 211 of the first signal line 21 extending along the row direction is at least part of the shielding unit 30, the place originally used for disposing the first line segment 211 along the column direction Y of the pixel driving circuits 10 is vacated. Accordingly, the pixel driving circuits 10 are compressed along the column direction Y of the pixel driving circuits 10, thus reducing the area of regions where the pixel driving circuits are located, contributing to the high resolution of the display panel, and meeting the requirements of light transmission and display in a high light-transmitting region.

It is to be understood that when a first signal line is a signal line electrically connected to the source or the drain of a first transistor in a pixel driving circuit and extending along the row direction of the pixel driving circuits, the signal line, for example, may be a reset signal line electrically connected to an initialization transistor and/or a reset transistor.

With further reference to FIGS. 13 and 14, since the signals transmitted by each reset signal line Ref are usually a same signal, each pixel driving circuit 10 may share a reset signal line Ref. In this case, the film layer P2 may be a non-patterned entire-layer structure. Alternatively, the film layer P2 may include a plurality of shielding sub-units. Each shielding sub-unit may overlap a plurality of first-type pixel driving circuits 101 such that the first-type pixel driving circuits 101 may share a reset signal line Ref. In this manner, the shielding performance of the shielding unit 30 is satisfied and the reset signal line Ref electrically connected to the first-type pixel driving circuit 101 has a relatively large cross-sectional area, thus decreasing losses of the signals transmitted on the reset signal line Ref and further enhancing the display effect of the display panel.

In an embodiment, with further reference to FIGS. 13 and 14, when at least one first transistor T1 includes an initialization transistor M4, the first signal line 21 may be the reset signal line electrically connected to the initialization transistor M4. Correspondingly, the pixel driving circuit 10 further includes a storage capacitor Cst. The initialization transistor M4 and the storage capacitor Cst are disposed sequentially along the column direction Y of the pixel driving circuits 10. The first metal layer P4 includes the second plate of the storage capacitor Cst. The second pole of the initialization transistor M4 and the second plate of the storage capacitor Cst are electrically connected at a first node N1. In this case, the display panel further includes the second metal layer P5 disposed on a side of the first metal layer P4 facing away from the base substrate P1, the third metal layer P6 disposed on a side of the second metal layer P5 facing away from the base substrate P1, and the first conductive layer P2. The second metal layer P5 includes the first plate of the storage capacitor Cst. The third metal layer P6 includes a plurality of fourth signal lines 24. The first plate of the storage capacitor Cst is electrically connected to a fourth signal line 24 through a third via hole H3. Moreover, storage capacitors Cst in at least part of the pixel driving circuits 10 disposed in the same column share a fourth signal line 24. The first conductive layer P2 includes the first line segments 211 and is disposed between the base substrate P1 and the semiconductor layer P3. A first via hole H13 electrically connected to the initialization transistor M4 is disposed on a side of a third signal line 23 facing the storage capacitor Cst.

Specifically, the arrangement in which at least part of the shielding unit 30 further serves as the reset signal line Ref electrically connected to the initialization transistor M4 in a first-type pixel driving circuit 101 enables the reset signal line Ref electrically connected to the initialization transistor M4 in a first-type pixel driving circuit 101 to be disposed in the first conductive layer P2, and vacates the place originally used for disposing the reset signal line Ref. That is, compared with the related art, the area of regions where the first-type pixel driving circuits 101 and the signal lines electrically connected to the first-type pixel driving circuits are located is reduced along the column direction Y of the pixel driving circuits 10. For example, the width of an original reset signal line Ref along the column direction of the pixel driving circuits 10 is in the range of 1 μm to 4 μm. The width of a pixel driving circuit 10 and a signal line electrically connected to the pixel driving circuit 10 along the row direction of the pixel driving circuits 10 is W μm. In this case, the area of regions where a first-type pixel driving circuit 101 and a signal line electrically connected to the first-type pixel driving circuit 101 are located may be at least reduced by W μm² to 4 W μm². Moreover, the arrangement in which the first conductive layer P2 also serving as the reset signal line Ref is disposed between the base substrate P1 and the semiconductor layer P3 enables the first via hole H13 to be directly disposed between the first conductive layer P2 and the semiconductor layer P3 so that the first pole of the initialization transistor M4 is electrically connected to the reset signal line Ref. Accordingly, on the basis of enhancing the resolution of the display pane and increasing the light-transmitting area of a high light-transmitting region, the technical process is simplified.

It is to be noted that FIG. 14 is only an exemplary drawing of embodiments of the present disclosure. FIG. 14 only illustrates that the first conductive layer P2 is disposed between the base substrate P1 and the semiconductor P3, by way of example. In embodiments of the present disclosure, the first conductive layer P2 may be disposed between the semiconductor layer P3 and the third metal layer P6.

For example, as shown in FIG. 15, the first conductive layer P2 is disposed between the second metal layer P5 and the third metal layer P6. In this manner, the first via hole H13 may also be directly disposed between the first conductive layer P2 and the semiconductor layer P3 so that the first pole of the initialization transistor M4 is electrically connected to the reset signal line Ref, simplifying the technical process.

It is to be understood that in addition to the preceding manner of layer arrangement, other manners of layer arrangement may be used. Under the premise that the first pole of the initialization transistor is electrically connected to the reset signal line and that the technical process is simplified, manners that can be conceived by those skilled in the art based on the description of the present disclosure are all within the scope of the present disclosure and is not repeated herein.

It is to be noted that, when the distance between the first conductive layer and the semiconductor layer is relatively long, to facilitate the arrangement of the first via hole, existing layers between the first conductive layer and the semiconductor layer may be used for forming a lap joint structure such that the first via hole is split into two sub-vias, thus reducing the arrangement difficulty of the first via hole.

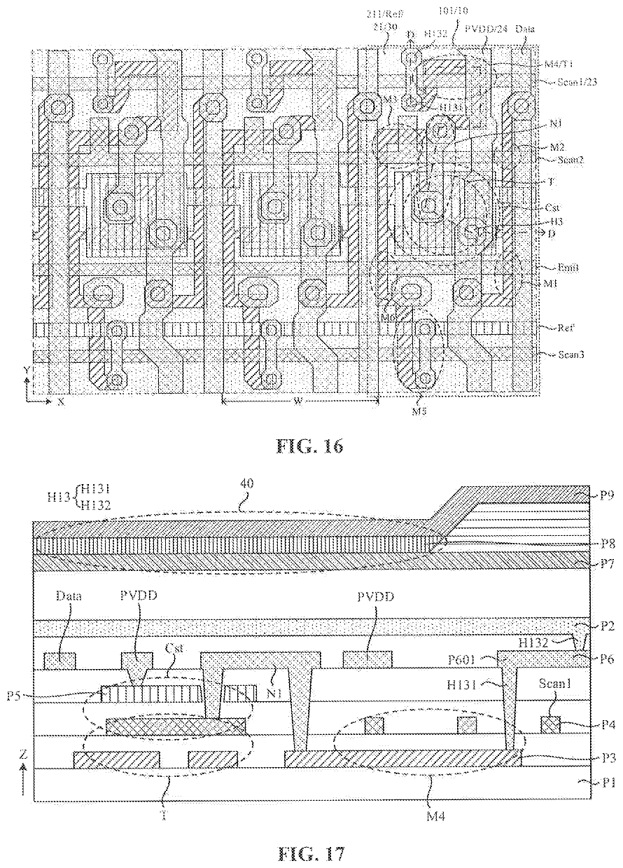

In an embodiment, FIG. 16 is a top view illustrating part of a display panel according to another embodiment of the present disclosure. FIG. 17 is a section view taken along section D-D of FIG. 16. Referring to FIGS. 16 and 17, when at least one first transistor T1 includes the initialization transistor M4, the pixel driving circuit 10 further includes a storage capacitor Cst. In this case, the initialization transistor M4 and the storage capacitor Cst are disposed sequentially along the column direction Y of the pixel driving circuits. The first metal layer P4 includes the second plate of the storage capacitor Cst. The second pole of the initialization transistor M4 and the second plate of the storage capacitor Cst are electrically connected to the first node N1. Correspondingly, the display panel further includes the second metal layer P5 disposed on a side of the first metal layer P4 facing away from the base substrate P1, the third metal layer P6 disposed on a side of the second metal layer P5 facing away from the base substrate P1, and the first conductive layer P2 disposed on a side of the third metal layer P6 facing away from the base substrate P1. The second metal layer P5 includes the first plate of the storage capacitor Cst. The third metal layer P6 includes a plurality of fourth signal lines 24 and a plurality of first lap joint structures P601. The first plate of the storage capacitor Cst is electrically connected to a fourth signal line 24 (PVDD) through the third via hole H3. Moreover, storage capacitors Cst in at least part of the pixel driving circuits 10 disposed in the same column share a fourth signal line 24 (PVDD). The first conductive layer P2 includes the first line segments 211. The first via hole H13 electrically connected to the initialization transistor M4 includes a first sub-via H131 and a second sub-via H132. The first pole of the initialization transistor M4 is electrically connected to a first lap joint structure P601 through the first sub-via H131. The first lap joint structure P601 is electrically connected to a first line segment 211 through the second sub-via H132. The first sub-via H131 is disposed on a side of a third signal line 23 facing the storage capacitor Cst. The second sub-via H132 is disposed on a side of the third signal line 23 facing away from the storage capacitor Cst.

With this arrangement, when the first conductive layer P2 is disposed on a side of the third metal layer P6 facing away from the base substrate P1, the distance between the first conductive layer P2 and the semiconductor layer P3 is relatively long. In this manner, a first lap joint structure P601 may be disposed in the third metal layer P6 such that the first via hole H13 is split into two sub-vias (the first sub-via H131 and the second sub-via H132), thus reducing the puncturing depth of a single via and reducing puncturing difficulty. Moreover, the arrangement in which the first lap joint structures P601 and the fourth signal lines 24 are disposed in the same layer simplifies the technical process, reduces the cost of the display panel, and contributes to the low cost of the display panel. Additionally, the arrangement in which the first sub-via H131 and the second sub-via H132 are disposed on two opposite sides of the third signal line 23 prevents the first sub-via H131 and the second sub-via H132 from affecting each other.

The preceding takes the first signal line as the reset signal line electrically connected to the first pole of the initialization transistor. In embodiments of the present disclosure, when the reset signal line electrically connected to the initialization transistor and the reset signal line electrically connected to the reset transistor are different reset signal lines, the first signal line may also be the reset signal line electrically connected to the reset transistor.

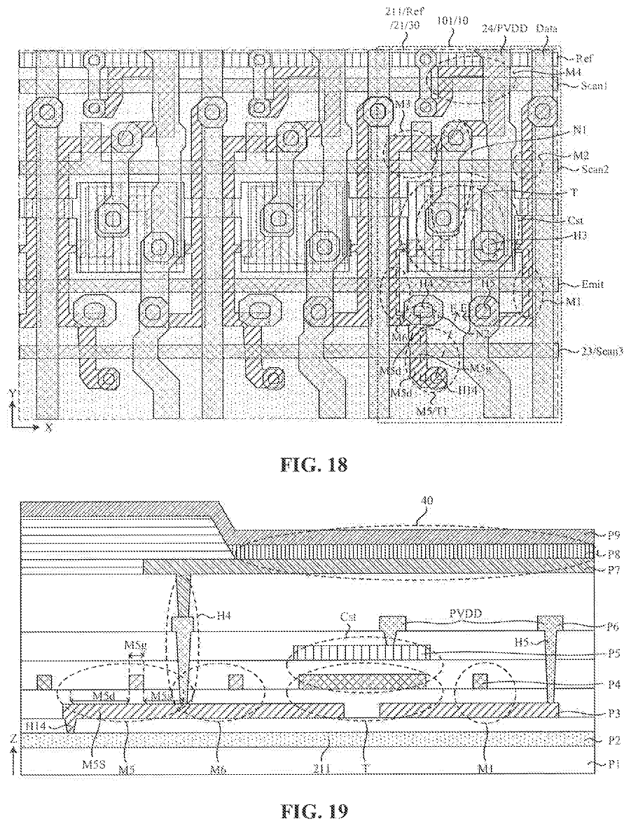

In an embodiment, FIG. 18 is a top view illustrating part of a display panel according to another embodiment of the present disclosure. FIG. 19 is a section view taken along section E-E of FIG. 18. Referring to FIGS. 18 and 19, the display panel further includes a plurality of light-emitting elements 40 disposed in an array. Each light-emitting element 40 is driven by the corresponding pixel driving circuit 10 to emit light. At least one first transistor T1 includes a reset transistor M5. The second pole of the reset transistor M5 is electrically connected to the anode of a light-emitting element 40 through a fourth via hole H4. In this case, along a direction perpendicular to the plane in which the base substrate P1 is located, the position where an active layer M5S of the reset transistor M5 overlaps the third signal line 23 is a channel region M5g of the reset transistor M5.

In the active layer M5S of the reset transistor M5, the region M5d from the channel region M5g of the reset transistor M5 to a first via hole H14 electrically connected to the reset transistor M5 and the region M5s from the channel region M5g of the reset transistor M5 to the fourth via hole H4 electrically connected to the reset transistor M5 are non-channel regions of the reset transistor M5. The ratio Sq of an area of the non-channel regions (M5s and M5d) of the reset transistor M5 to an area of the channel region M5g of the reset transistor M5 satisfies 1.5≤Sq≤2.

Specifically, when the at least one first transistor T1 includes a reset transistor M5, the first signal line 21 electrically connected to the source or the drain of the reset transistor is a reset signal line Ref′. In this case, at least part of the shielding unit 30 further serves as the reset signal line Ref′ electrically connected to the reset transistor M5 in a first-type pixel driving circuit 101. With this arrangement, the size of the active layer of the reset transistor M5 is reduced along the column direction Y of the pixel driving circuits 10 so that the area ratio of the non-channel regions (M5s and M5d) of the reset transistor M5 to the channel region M5g of the reset transistor M5 is reduced to the range from 1.5 to 2. Compared with the related art, the size of the active layer of the reset transistor M5 is relatively reduced by 30% to 60% along the column direction Y of the pixel driving circuits 10. In this manner, the arrangement in which at least part of the shielding unit 30 further serves as the reset signal line Ref′ electrically connected to the reset transistor M5 helps reduce the size of the reset transistor M5. Accordingly, the area of regions where the pixel driving circuits 10 are located is reduced, thus increasing the number of the pixel driving circuits 10 disposed in the display panel, contributing to the high resolution of the display panel, and meeting the requirements of display in a high light-transmitting region.

In an embodiment, with further reference to FIGS. 18 and 19, when at least one first transistor T1 includes the reset transistor M5, the pixel driving circuit 10 may further include light-emitting control transistors (M1 and M6) and a driving transistor T. The driving transistor T, the light-emitting control transistors (M1 and M6), and the reset transistor M5 are disposed sequentially along the column direction Y of the pixel driving circuits 10. The light-emitting control transistors include a first light-emitting control transistor M1 and a second light-emitting control transistor M6. Correspondingly, the display panel further includes the third metal layer P6 disposed on a side of the first metal layer P4 facing away from the base substrate P1, display layers (P7, P8, and P9) disposed on a side of the third metal layer P6 facing away from the base substrate, and the first conductive layer P2. The third metal layer P6 includes a plurality of fourth signal lines 24. The display layers (P7, P8, and P9) include a plurality of light-emitting elements 40 disposed in an array. The first conductive layer P2 includes the first line segments 211 and is disposed between the base substrate P1 and the semiconductor layer P3. In this case, the first pole of the first light-emitting control transistor M1 is electrically connected to a fourth signal line 24 through a fifth via hole H5. The second pole of the first light-emitting control transistor M1 is electrically connected to the first pole of the driving transistor T. The first pole of the second light-emitting control transistor M6 is electrically connected to the second pole of the driving transistor T. The second light-emitting control transistor M6 and the reset transistor M5 are electrically connected at a second node N2. The second light-emitting control transistor M6 and the reset transistor M5 are both electrically connected to the anode of the light-emitting element 40 through the fourth via hole H4 at the second node N2. The first via hole H14 electrically connected to the reset transistor M5 is disposed on a side of the third signal line 23 facing away from the fourth via hole H4 and the fifth via hole H5.

In this manner, the arrangement in which the first conductive layer P2 is disposed between the base substrate P1 and the semiconductor layer P3 guarantees a relatively short distance between the first conductive layer P2 and the semiconductor layer P3 and thus enables the first via hole H13 to be directly disposed between the first conductive layer P2 and the semiconductor layer P3 so that the reset transistor M5 is electrically connected to the reset signal line Ref′. Accordingly, on the basis of enhancing the resolution of the display pane and increasing the light-transmitting area of a high light-transmitting region, the technical process is simplified.

It is to be noted that FIG. 19 is only an exemplary drawing of embodiments of the present disclosure. FIG. 19 only illustrates that the first conductive layer P2 is disposed between the base substrate P1 and the semiconductor P3, as an example. In embodiments of the present disclosure, the first conductive layer P2 may be disposed between the semiconductor layer P3 and the third metal layer P6.

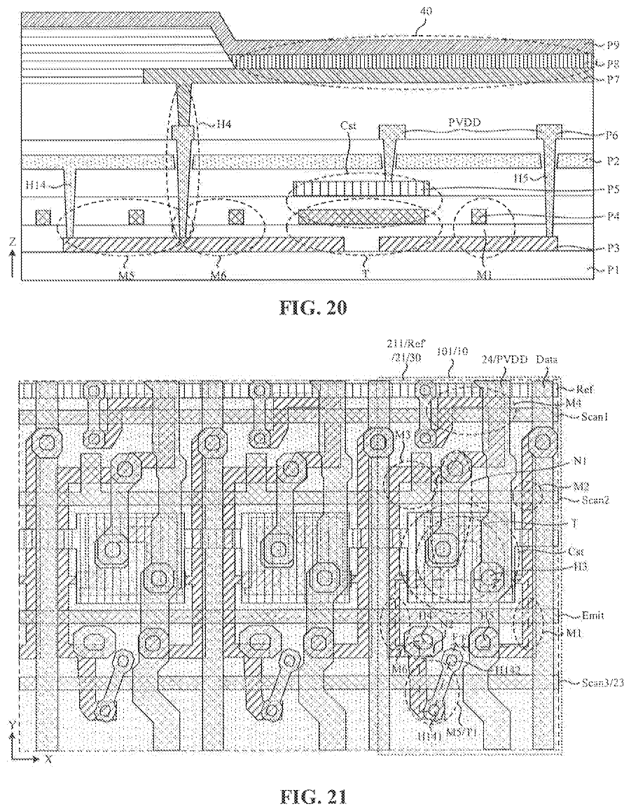

For example, as shown in FIG. 20, the first conductive layer P2 is disposed between the second metal layer P5 and the third metal layer P6. In this manner, the first via hole H14 may also be directly disposed between the first conductive layer P2 and the semiconductor layer P3 so that the first pole of the reset transistor M5 is electrically connected to the reset signal line Ref′, simplifying the technical process.

It is to be understood that in addition to the preceding manner of layer arrangement, other manners of layer arrangement may be used. Under the premise that the first pole of the reset transistor M5 is electrically connected to the reset signal line Ref′ and that the technical process is simplified, manners that can be conceived by those skilled in the art based on the description of the present disclosure are all within the scope of the present disclosure and is not repeated herein.

It is to be noted that, when the distance between the first conductive layer and the semiconductor layer is relatively large, to facilitate the arrangement of the first via hole, existing layers between the first conductive layer and the semiconductor layer may be used for forming a lap joint structure such that the first via hole is split into two sub-vias, thus reducing the arrangement difficulty of the first via hole.

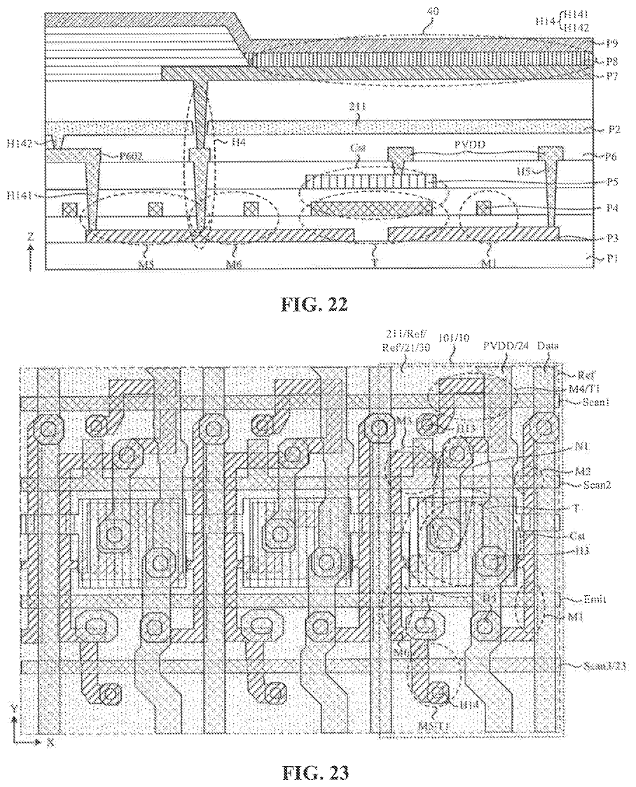

In an embodiment, FIG. 21 is a top view illustrating part of a display panel according to another embodiment of the present disclosure. FIG. 22 is a section view taken along section F-F of FIG. 21. Referring to FIGS. 21 and 22, when at least one first transistor T1 includes the reset transistor M5, the pixel driving circuit 10 may further include the light-emitting control transistors (M1 and M6) and the driving transistor T. The driving transistor T, the light-emitting control transistors (M1 and M6), and the reset transistor M5 are disposed sequentially along the column direction Y of the pixel driving circuits 10. The light-emitting control transistors include the first light-emitting control transistor M1 and the second light-emitting control transistor M6. The display panel further includes the third metal layer P6 disposed on a side of the first metal layer P4 facing away from the base substrate P1, the display layers (P7, P8, and P9) disposed on a side of the third metal layer P6 facing away from the base substrate P1, and the first conductive layer P2 disposed between the display layers (P7, P8, and P9) and the third metal layer P6. The third metal layer P6 includes a plurality of fourth signal lines 24 and a plurality of second lap joint structures P602. The display layers (P7, P8, and P9) include a plurality of light-emitting elements disposed in an array. The first conductive layer P2 includes the first line segments 211. Correspondingly, the first pole of the first light-emitting control transistor M1 is electrically connected to a fourth signal line 24 through the fifth via hole H5. The second pole of the first light-emitting control transistor M1 is electrically connected to the first pole of the driving transistor T. The first pole of the second light-emitting control transistor M6 is electrically connected to the second pole of the driving transistor T. The second light-emitting control transistor M6 and the reset transistor M5 is electrically connected at the second node N2. The second light-emitting control transistor M6 and the reset transistor M5 are both electrically connected to the anode of a light-emitting element 40 through the fourth via hole H4 at the second node N2. In this case, the first via hole H14 electrically connected to the reset transistor M5 includes a third sub-via H141 and a fourth sub-via H142. The first pole of the reset transistor M5 is electrically connected to a second lap joint structure P602 through the third sub-via H141. The second lap joint structure P602 is electrically connected to a first line segment 211 through the fourth sub-via H142. The third sub-via H141 is disposed on a side of the third signal line 23 facing away from the fourth via H14. Along a direction perpendicular to the plane in which the base substrate P1 is located, the fourth sub-via H142 overlaps the region between the fourth via hole H4 and the fifth via hole H5.

With this arrangement, when the first conductive layer P2 is disposed between the display layers (P7, P8, and P9) and the third metal layer P6, the distance between the first conductive layer P2 and the semiconductor layer P3 is relatively long. In this manner, a second lap joint structure P602 may be disposed in the third metal layer P6 such that the first via hole H14 is split into two sub-vias (the third sub-via H141 and the fourth sub-via H142), thus reducing the puncturing depth of a single via and reducing puncturing difficulty. Moreover, the arrangement in which the second lap joint structures P602 and the fourth signal lines 24 are disposed in the same layer simplifies the technical process, reduces the cost of the display panel, and contributes to the low cost of the display panel. Additionally, the arrangement in which the third sub-via H141 and the fourth sub-via H142 are disposed on two opposite sides of the third signal line 23 prevents the third sub-via H141 and the fourth sub-via H142 from affecting each other. When the fourth sub-via H142 overlaps the region between the fourth via hole H4 and the fifth via hole H5, space utilization is enhanced, further reducing the area of regions where the pixel driving circuits 10 are located.

It is to be noted that the preceding illustrates the in which two reset signal lines electrically connected to the initialization transistor and the reset transistor in the same pixel driving circuit also serve as a shielding unit as an example. In embodiments of the present disclosure, each of the two reset signal lines electrically connected to the initialization transistor and the reset transistor in the same pixel driving circuit may also serve as a shielding unit. As shown in FIG. 23, when the reset signal line Ref and the reset signal line Ref′ electrically connected to the initialization transistor and the reset transistor in the same pixel driving circuit 10 respectively also serve as a shielding unit 30, the size of the region where the pixel driving circuit 10 is located is further reduced.

It is to be understood that the preceding is an exemplary description with an example in which a first signal line is a signal line electrically connected to the source or the drain of a transistor in a pixel driving circuit. In embodiments of the present disclosure, the first signal line may further be a signal line electrically connected to the gate of the transistor in the pixel driving circuit.

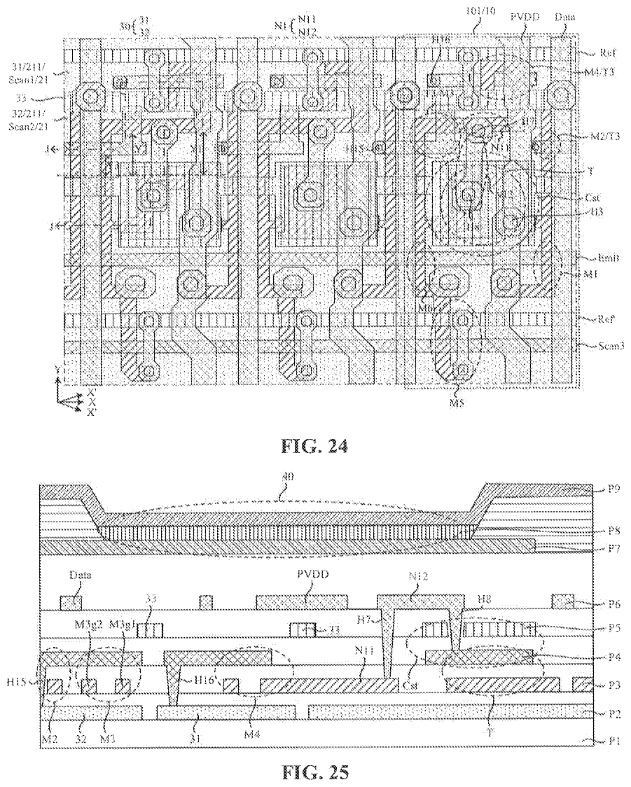

In an embodiment, FIG. 24 is a top view illustrating part of a display panel according to another embodiment of the present disclosure. FIG. 25 is a section view taken along section J-J of FIG. 24. Referring to FIGS. 24 and 25, the pixel driving circuit 10 includes at least one third transistor T3. The pixel driving circuit 10 electrically connected to a first line segment 211 of a first signal line 21 refers to a first-type pixel driving circuit 101. The gate of a third transistor T3 in the first-type pixel driving circuit 101 is electrically connected to the first line segment 211 through a first via hole H15. Gates of any two third transistors T3 in the same first-type pixel driving circuit 101 are insulated from each other.

Specifically, through the arrangement in which gates of any two third transistors T3 in the same first-type pixel driving circuit 101 are insulated from each other, only the gate structures of the third transistors T3 are retained in the film layer P4 where the gates of the third transistors T3 are located. The first line segment 211 electrically connected to a third transistor T3 is disposed in the film layer P2 where the shielding unit 30 is located. Compared with the condition in which both the gates of the third transistors T3 and the signal lines electrically connected to the gates of the third transistors T3 are disposed in the film layer where the gates of the third transistors T3 are located, this arrangement vacates the region between two third transistors T3 whose gates are insulated from each other so that other structures of the first-type pixel driving circuit 101 are movable thereto, thus reducing the size of the first-type pixel driving circuit, contributing to the high resolution of the display panel, and meeting the requirements of light transmission and display in a high light-transmitting region.

In an embodiment, with further reference to FIGS. 24 and 25, at least one third transistor T3 may include a data writing transistor M2 and a threshold compensation transistor M3. The pixel driving circuit 10 may further include the driving transistor T and the initialization transistor M4. The data writing transistor M2 and the threshold compensation transistor M3 are disposed sequentially along the row direction X of the pixel driving circuits 10. The initialization transistor M4, the threshold compensation transistor M3, and the driving transistor are disposed sequentially along the column direction Y of the pixel driving circuits 10. The second pole of the data writing transistor M2 is electrically connected to the first pole of the driving transistor T. The first pole of the threshold compensation transistor M3 is electrically connected to the second pole of the driving transistor T. The second pole of the initialization transistor M4, the second pole of the threshold compensation transistor M3, and the gate of the driving transistor T are electrically connected to the first node N1. The data writing transistors M2 and threshold compensation transistors M3 in at least part of the pixel driving circuits 10 in the same row share a first signal line 21 (Scan 2). In a first-type pixel driving circuit 101, the gate of the data writing transistor M2 and the gate of the threshold compensation transistor M3 are electrically connected to the same first line segment 211.

Specifically, when at least one third transistor T3 may include the data writing transistor M2 and the threshold compensation transistor M3, the first signal line 21 electrically connected to the data writing transistor M2 and the threshold compensation transistor M3 is a second scanning signal line Scan2. The arrangement in which at least part 32 of the shielding unit 30 further serves as the second scanning signal line Scan2 electrically connected to the gate of the data writing transistor M2 in the first-type pixel driving circuit 101 and the gate of the threshold compensation transistor M3 in the first-type pixel driving circuit 101 enables the first node N1 to be disposed in the region between the threshold compensation transistor M3 and the data writing transistor M2 in the same first-type pixel driving circuit 101. That is, compared with the related art, a partial structure of the first node N1 is movable toward the driving transistor T so that the initialization transistor M4 moves along with the partial structure of the first node N1. Accordingly, along the column direction Y of the pixel driving circuits 10, the size of the first-type pixel driving circuit 101 is reduced.

In an embodiment, with further reference to FIGS. 24 and 25, the display panel 100 includes the semiconductor layer P3 disposed on a side of the base substrate P1 and the first metal layer P4 disposed on a side of the semiconductor layer P3 facing away from the base substrate. The semiconductor layer P3 includes an active layer of the data writing transistor T2, an active layer of the threshold compensation transistor M3, an active layer of the initialization transistor M4, and an active layer of the driving transistor T. The active layer includes a channel region and a first pole and a second pole that are disposed on two sides of the channel region. The first metal layer P4 includes a gate of the data writing transistor T2, a gate of the threshold compensation transistor M3, a gate of the initialization transistor M4, and a gate of the driving transistor T. Along a direction Z perpendicular to the plane in which the base substrate P1 is located, the position where the active layer overlap the gate is the channel region of the active layer. The first node N1 includes a first sub-section N11 and a second sub-section N12. The first sub-section N11 extends along the row direction X of the pixel driving circuits 10 and is configured to electrically connect the second pole of the threshold compensation transistor M3 to the second pole of the initialization transistor M4. The second sub-section N12 extends along the column direction Y of the pixel driving circuits 10 and is configured to electrically connect the first sub-section N11 to the gate of the driving transistor T. Along a direction Z perpendicular to the plane in which the base substrate P1 is located, the first sub-section N11 and the second sub-section N12 do not overlap each other.

Specifically, when the first sub-section N11, the second pole of the threshold compensation transistor M3, and the second pole of the initialization transistor M4 are disposed in the same layer. The second pole of the initialization transistor M4, the first sub-section N11, and the second pole of threshold compensation transistor M3 may be disposed sequentially along the row direction X of the pixel driving circuits 10. The second scanning signal line Scan electrically connected to the gate of the threshold compensation transistor M3 and the gate of the data writing transistor M2 in the same first-type pixel driving circuit 101 is disposed in different layers (P2 and P4) from the gate of the threshold compensation transistor M3 and the gate of the data writing transistor M2. When the sub-section of the first sub-section N11 is disposed in the region between the gate of the threshold compensation transistor M3 and the gate of the data writing transistor M2, the first sub-section N11 does not overlap structures of the film layer in which the gate of the threshold compensation transistor M3 and the gate of the data writing transistor M2 are located. In this manner, a transistor is not formed in the position of the first sub-section N11. Accordingly, an overlap between the first sub-section N11 and the structures of the film layer in which the gate of the threshold compensation transistor M3 and the gate of the data writing transistor M2 are located is prevented from causing a transistor to be formed in the position where no transistor is supposed to be formed, and is further prevented from affecting the performance of the pixel driving circuits.

In an embodiment, with further reference to FIGS. 24 and 25, the active layer of the threshold compensation transistor M3 includes a first channel region M3g1 and a second channel region M3g2. Along a second direction X′, the second pole of the initialization transistor M4 and the first sub-section N11 overlap the first channel region M3g1 and/or the second channel region M3g2. The second direction X′ is parallel to the plane in which the base substrate P1 is located. A second included angle is disposed between the second direction X′ and the row direction X of the pixel driving circuits 10.

Specifically, the arrangement in which the gate of the threshold compensation transistor M3 and the gate of the data writing transistor M2 are insulated from each other enables the first sub-section N11 to be disposed in the region between the gate of the threshold compensation transistor M3 and the gate of the data writing transistor M2. That is, compared with the related art, the first sub-section N11 and the second pole of the initialization transistor M4 are movable toward the driving transistor T. With this arrangement, the distance from the first sub-section N11 and the second pole of the initialization transistor M4 to the driving transistor T is Yl. The distance between the first channel region M3g1 of the threshold compensation transistor M3 and the driving transistor is Y2. The second channel region M3g2 of the threshold compensation transistor M3 and the driving transistor is Y3. Y1 may be between Y2 and Y3, equivalent to Y2, or equivalent to Y3. Accordingly, along the direction (the second direction X′) which has a relatively small included angle (the second angle) with the row direction X of the pixel driving circuits 10, the second pole of the initialization transistor M4 and the first sub-section N11 may overlap the first channel region M3g1 and/or the second channel region M3g2. The second included angle may be a relatively small included angle so that the second direction X′ is approximately parallel to the row direction X of the pixel driving circuits 10.

In an embodiment, with further reference to FIGS. 24 and 25, when the display panel includes the third metal layer P6 disposed on a side of the first metal layer P4 facing away from the base substrate P1, the third metal layer P6 may include the second sub-section N12. The first sub-section N11 is disposed in the semiconductor layer P3. One end of the second sub-section N12 is electrically connected to the first sub-section N11 through a seventh via hole H7. The other end of the second sub-section N12 is electrically connected to the gate of the driving transistor T through an eighth via hole H8.

Specifically, the first sub-section N11 of the first node N1 and the second sub-section N12 of the first node are disposed in the semiconductor layer P3 and the third metal layer P6 respectively. Compared with the related are, only the structure of the semiconductor layer P3 for disposing the first sub-section N11 needs to be changed while the structure of the third metal layer P6 disposing the second sub-section N12 and the structure of the driving transistor T may be unchanged. This simplifies the design of the pixel driving circuits.

It is to be noted that FIGS. 24 and 25 are only exemplary drawings of embodiments of the present disclosure. FIGS. 24 and 25 only illustrate that the first sub-section N11 and the second sub-section N12 are disposed in different film layers respectively as an example. In embodiments of the present disclosure, the first sub-section N11 and the second sub-section N12 may be separately disposed in a same film layer.

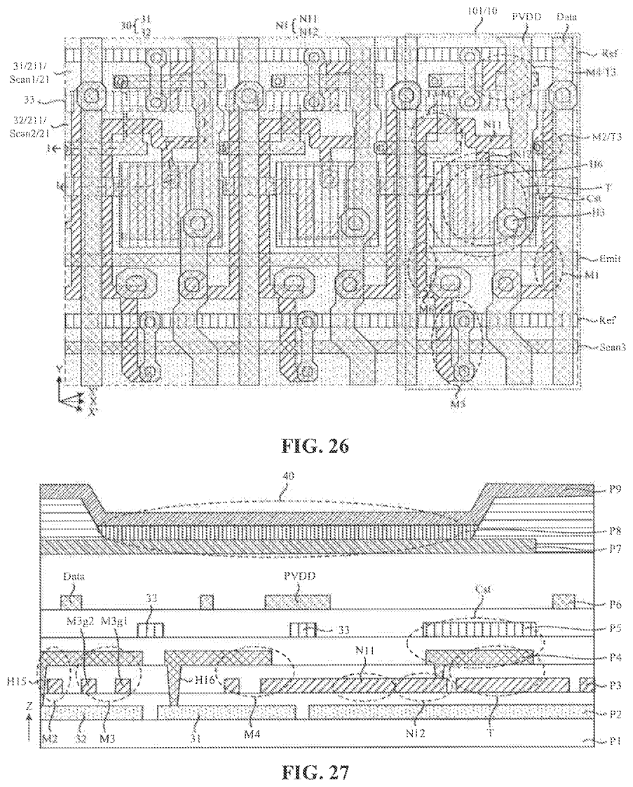

In an embodiment, FIG. 26 is a top view illustrating part of a display panel according to another embodiment of the present disclosure. FIG. 27 is a section view taken along section I-I of FIG. 26. Referring to FIGS. 26 and 27, the first sub-section N11 and the second sub-section N12 are both disposed in the semiconductor layer P3. One end of the second sub-section is electrically connected to the first sub-section. The other end of the second sub-section is electrically connected to the gate of the driving transistor T through a sixth via hole H6. When the second channel region M3g2 is disposed on a side of the first channel region M3g1 facing the driving transistor T, the first sub-section N11 is disposed on a side of the first channel region M3g1 facing the driving transistor T.

In this manner, the arrangement in which the first sub-section N11 and the second sub-section N12 are disposed in the same layer (the semiconductor layer P3) enables the first sub-section N11 and the second sub-section N12 to be formed using the same process. Further, the first sub-section N11 and the second sub-section N12 may be formed as an integral structure with no via needed for electrically connected the first sub-section N11 and the second sub-section N12, thus simplifying the technical process and reducing the cost of the display panel. Moreover, the arrangement in which the first sub-section N11 is disposed on a side of the first channel M3g1 facing the driving transistor T helps vacate the region on a side of the first sub-section N11 facing away from the driving transistor T so that the region is used for disposing other structures of the first-type pixel driving circuit 101, thus further reducing the first-type pixel driving circuit 101.

It is to be noted that the second pole of the threshold compensation transistor M3 is electrically connected to the gate of the driving transistor T. In the light-emitting phase, the driving transistor T may generate a drive current based on the potential of the gate to drive a light-emitting element 40 to exhibit a corresponding luminance. That is, the gate potential of the driving transistor T may directly affect the luminance of the light-emitting element. Accordingly, to prevent the gate potential of the driving transistor T from being affected by the current leakage generated by the threshold compensation transistor M3 in the light-emitting phase, the threshold compensation transistor M3 is usually provided as a transistor of a double-gate structure to enable the threshold compensation transistor M3 to have a relatively small leakage current. That is, the threshold compensation transistor M3 usually includes a first gate and a second gate. The first gate overlaps the first channel region M3g1 of the threshold compensation transistor M3. The second gate overlaps the second channel region M3g2 of the threshold compensation transistor M3. The first gate of the threshold compensation transistor M3 and the second gate of the threshold compensation transistor M3 are usually an integral structure. In embodiments of the present disclosure, the first gate of the threshold compensation transistor M3 and the second gate of the threshold compensation transistor M3 may further be two independent structures.

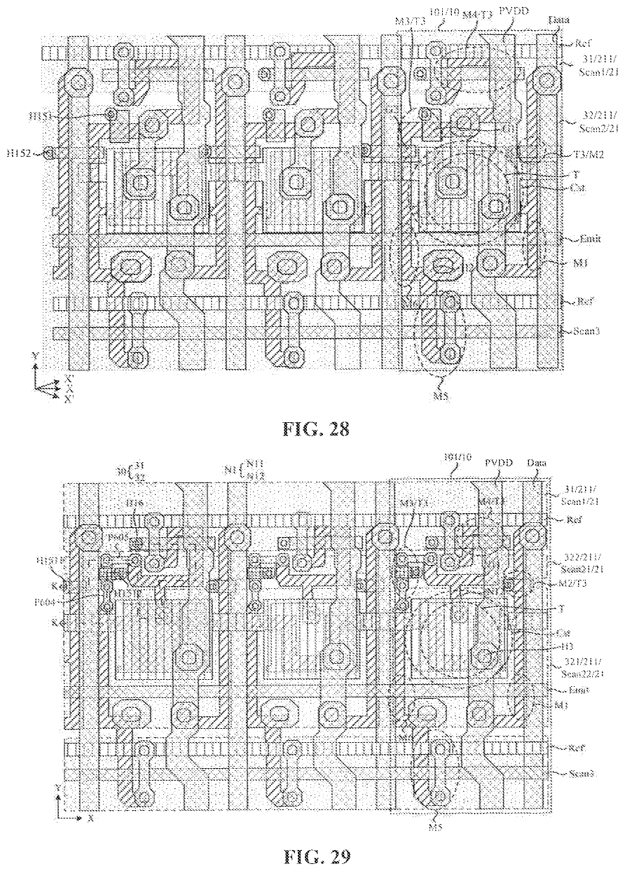

In an embodiment, FIG. 28 is a top view illustrating part of a display panel according to another embodiment of the present disclosure. As shown in FIG. 28, when the gate of the threshold compensation transistor M3 includes a first gate G1 and a second gate G2, the first gate G1 overlaps the first channel region and the second gate G2 overlaps the second channel region. Moreover, when the first gate and the second gate are insulated from each other, the second gate G2 overlaps the driving transistor T along the second direction X′.

Specifically, the arrangement in which the first gate G1 and the second gate G2 of the same threshold compensation transistor M3 are disposed separately. The first gate G1 and the second gate G2 are electrically connected to the same first line segment 211 through a first via hole H151 and a first via hole H152 respectively so that the first gate G1 and the second gate G2 of the same threshold compensation transistor M3 receive second scanning signals synchronously. Moreover, when the first gate G1 and the second gate G2 of the same threshold compensation transistor M3 are disposed separately, the region between the first gate G1 and the second gate G2 is vacated in the film layer where the first gate G1 and the second gate G2 are located, so that the region is used for disposing other structures of the pixel driving circuit. Compared with the related art, for example, the driving transistor T may be moved to the region between the first gate G1 and the second gate G2. In this case, along the column direction Y of the pixel driving circuits, the distance from the active layer (in the shape of Chinese character “n” as illustrated in the drawing) of the driving transistor T to the region between the first gate G1 and the second gate G2 may be shortened. Accordingly, along the direction X′ which has a relatively small included angle (the second angle) with the row direction X of the pixel driving circuits 10, the second gate G2 overlaps the active layer of the driving transistor T. The second included angle may be a relatively small included angle. In this case, the second direction X′ is approximately parallel to the row direction X of the pixel driving circuits 10.

Additionally, the pixel driving circuit 10 usually may further include the storage capacitor Cst. The second plate of the storage capacitor Cst further serves as the gate of the driving transistor T. Accordingly, when the second gate G2 overlaps the active layer of the driving transistor T along the second direction X′, the second gate G2 may also overlap the drive storage capacitor Cst along the second direction X′. Even along the row direction of the pixel driving circuits 10, the second gate G2 may also overlap the drive storage capacitor Cst.

It is to be noted that the preceding arrangement in which the threshold compensation transistor M3 of a double-gate structure is provided reduces the current leakage of the threshold compensation transistor M3. In embodiments of the present disclosure, by changing the material of the threshold compensation transistor, the threshold compensation transistor may also be provided as a single-gate structure, for example, a single-gate threshold compensation transistor prepared by using the LTPO process, which may be implemented to reduce the current leakage of the threshold compensation transistor.

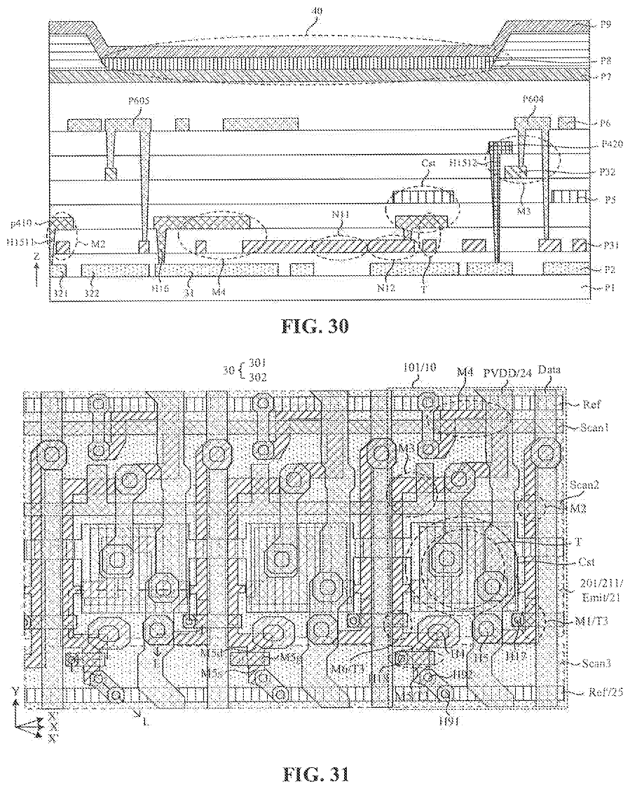

For example, FIG. 29 is a top view illustrating part of a display panel according to another embodiment of the present disclosure. FIG. 30 is a section view taken along section K-K of FIG. 29. Referring to FIGS. 29 and 30, the threshold compensation transistor M3 only includes one gate. In this case, the active layer of the threshold compensation transistor M3 may be disposed in an oxide semiconductor P32. Active layers of other transistors (the driving transistor T and the data writing transistor M2) may be disposed in a low-temperature polysilicon semiconductor layer P31. With this arrangement, other transistors have relatively large response speeds. Under the premise that the threshold compensation transistor M3 is of a single-gate structure, the current leakage is relatively small and the size of the threshold compensation transistor M3 is reduced. Accordingly, the size of the pixel driving circuit including the threshold compensation transistor M3 is further reduced. Moreover, when an active layer M3g of the threshold compensation transistor M3 is disposed in the oxide semiconductor P32 and an active layer M2g of the data writing transistor M2 is disposed in the low-temperature polysilicon semiconductor layer P31, the channel type of the threshold compensation transistor M3 is different from the channel type of the data writing transistor M2. In this case, the gate of the threshold compensation transistor M3 and the gate of the data writing transistor M2 need to be electrically connected to different first line segments 321 (Scan21) and 322 (Scan22) through a first via hole H1511 and a first via hole H1512 respectively so that it is ensured that the threshold compensation transistor M3 and the data writing transistor M2 can turn on simultaneously under the control of different second scanning signals.

Correspondingly, gate metal layers include a first gate metal layer P410 and a second gate metal layer P420. The first gate metal layer P410 is provided with the gates of transistors, including the data writing transistor M2, whose active layers are disposed in the low-temperature polysilicon semiconductor layer P31. Material of the first gate metal layer P410, for example, may be molybdenum. The second gate metal layer P420 is provided with the gate of the threshold compensation transistor. Material of the second gate metal layer P420 may include molybdenum and titanium. Moreover, the low-temperature polysilicon semiconductor layer P31 and the oxide semiconductor P32 are disposed in different layers. In this case, the first pole of the threshold compensation transistor M3 may be electrically connected to the second pole of the driving transistor T through an lap joint structure P604 disposed in the third metal layer P6. The second pole of the threshold compensation transistor M3 may be electrically connected to the initialization transistor M4 and the first node N1 through an lap joint structure P605 disposed in the third metal layer P6.

Moreover, when a first signal line is a signal line electrically connected to the gate of a transistor, the first signal line may be the first scanning signal line electrically connected to the gate of the initialization transistor. With further reference to FIGS. 24 and 25, at least one third transistor T3 may include an initialization transistor M4. The first signal lines 21 include the first scanning signal line Scanl electrically connected to the gate of the initialization transistor M4. In this case, a portion 31 of a shielding unit 30 may also serve as the first scanning signal line Scan1 electrically connected to the initialization transistor M4 so that the gate of the initialization transistor M4 may be electrically connected to the first scanning signal line Scan1 through a first via hole H16. In this case, the region between gates of two adjacent initialization transistors M4 may be used for disposing other structures so that the area of regions where the first-type pixel driving circuits 101 are located is further reduced.

Moreover, the portion 31 of a shielding unit 30 and another portion 32 of the shielding unit 30 also serve as different scanning signal lines (the first scanning signal line Scan1 and the second scanning signal line Scan2) respectively. In this case, as the first scanning signals transmitted by the first scanning signal line Scan' and the second scanning signals transmitted by the second scanning signal line Scan2 are different, and the first scanning signals and the second scanning signals are both variable voltage signals, the portion 31 and the portion 32 of the shielding unit 30 should be insulated from each other. That is, the portion 31 and the portion 32 of the shielding unit 30 disposed in the first conductive layer P2 are spaced apart, and in accordance, a gap exists between the two portion 31 and the portion 32 of the shielding unit 30. The gap may affect the shielding effect of the shielding unit 31. In this case, under the premise of not affecting elements and signals in the display panel, existing film layers in the display panel may be used for filling the gap. For example, apart from including the first plate of the storage capacitor Cst, the second metal layer P5 may further include a second shielding structure 33. The second shielding structure 33 overlaps the gap between the portion 31 and the portion 32 of the shielding unit 30 in the first conductive layer P2 so as to enhance the shielding effect of the shielding unit 30.

It is to be noted that FIGS. 24 and 25 only for example illustrate that the second shielding structures 33 are disposed in the second metal layer P5. In embodiments of the present disclosure, the third shielding structures may be disposed in the anode metal layer where the anodes of the organic light-emitting elements are located. Moreover, under the premise of meeting the shielding requirements of the shielding unit, the second shielding structure and the third shielding structure may be both or either provided. Additionally, under the premise of not affecting other structures in the display panel, shielding structures may be disposed in other metal layers to guarantee the good shielding performance of the shielding unit 30.

It is to be understood that the preceding for example illustrates that when at least one third transistor includes the threshold compensation transistor, the data writing transistor, and the initialization transistor, the size of the first-type pixel driving circuit is reduced. In embodiments of the present disclosure, when the pixel driving circuit further includes other transistors needed to be controlled by scanning signals, the at least one third transistor may further include other transistors.

In an embodiment, FIG. 31 is a top view illustrating part of a display panel according to another embodiment of the present disclosure. FIG. 32 is a section view taken along section L-L of FIG. 31. Referring to FIGS. 31 and 32, at least one third transistor T3 includes the first light-emitting control transistor M1 and the second light-emitting control transistor M6. Moreover, the pixel driving circuit further includes the driving transistor T. Correspondingly, the display panel further includes a plurality of light-emitting elements 40 disposed in an array and a plurality of fourth signal lines 24. The first pole of the first light-emitting control transistor M1 is electrically connected to a fourth signal line 24 through the fifth via hole H5. First light-emitting control transistor M1 in at least part of the pixel driving circuits in the same column share a fourth signal line 24. The second pole of the first light-emitting control transistor M1 is electrically connected to the first pole of the driving transistor T. The first pole of the second light-emitting control transistor M6 is electrically connected to the second pole of the driving transistor T. The second light-emitting control transistor M6 is electrically connected to the anode of a light-emitting element 40 through the fourth via hole H4. Along the second direction X′, the fifth via hole H5 and the fourth via hole H4 overlap the gate of the first light-emitting control transistor M1 and/or the gate of the second light-emitting control transistor M6. The second direction X′ is parallel to the plane in which the base substrate P1 is located. A second included angle is disposed between the second direction X′ and the row direction of the pixel driving circuits 10.

Specifically, the gate of the first light-emitting control transistor M1 and the gate of the second light-emitting control transistor M6 sharing a first signal line 21 (Emit) are insulated from each other. That is, the first light-emitting control transistor M1 and the second light-emitting control transistor M6 are independent of each other. With this arraignment, the region between the gate of the first light-emitting control transistor M1 and the gate of the second light-emitting control transistor M6 may be used for disposing other structures. In this case, the fifth via hole H5 electrically connecting the first light-emitting control transistor M1 to the fourth signal line 24 (PVDD) and the fourth via hole H4 electrically connecting the second light-emitting control transistor M6 to the anode of the light-emitting element 40 may be disposed in the region between the gate of the first light-emitting control transistor M1 and the gate of the second light-emitting control transistor M6. No additional region is needed for disposing the fourth via hole H4 and the fifth via hole H5, thus reducing the size of the first-type pixel driving circuit, contributing to the high resolution of the display panel, and meeting the requirements of light transmission and display in a high light-transmitting region in the display panel. Moreover, when the fourth via hole H4 and the fifth via hole H5 are disposed in the region between the gate of the first light-emitting control transistor M1 and the gate of the second light-emitting control transistor M6, the fourth via hole H4 and the fifth via hole H5 may overlap the gate of the first light-emitting control transistor M1 and the gate of the second light-emitting control transistor M6 simultaneously along the second direction X′ approximately parallel to the row direction X of the pixel driving circuits 10. Alternatively, the fourth via hole H4 and the fifth via hole H5 overlap one of the gate of the first light-emitting control transistor M1 and the gate of the second light-emitting control transistor M6.

Correspondingly, the first line segment 211 (Emit) electrically connected to the gate of the first light-emitting control transistor M1 and the gate of the second light-emitting control transistor in a first-type pixel driving circuit 101 further serves as a portion 301 of the shielding unit 30. The gate of the first light-emitting control transistor M1 and the gate of the second light-emitting control transistor M6 are only retained in the first metal layer P4 so that the gate of the first light-emitting control transistor M1 and the gate of the second light-emitting control transistor M6 are electrically connected to the portion 301 of the shielding unit 30 through a first via hole H17.

In an embodiment, with further reference to FIGS. 31 and 32, at least one third transistor T3 includes the reset transistor M5. Correspondingly, the display panel further includes a plurality of light-emitting elements 40 disposed in an array and a plurality of fifth signal lines 25 (Ref′). In this case, the first pole of the reset transistor M5 is electrically connected to a fifth signal line 25 (Ref′). Moreover, reset transistors M5 in at least part of the pixel driving circuits 10 in the same row share a fifth signal line 25 (Ref′). The second pole of the reset transistor M5 is electrically connected to the anode of a light-emitting element 40.

With this arrangement, in the first metal layer P5 where the gate of the reset transistor M5 is located, only the gate of the reset transistor M5 is retained to vacate the region between gates of two adjacent reset transistors M5 so that the region is used for disposing other structures of a first-type pixel driving circuit 101, thus reducing the area of the region where the first-type pixel driving circuit 101 is located.

In an embodiment, with further reference to FIGS. 31 and 32, when at least one third transistor T3 includes the reset transistor M5, the display panel may further include the semiconductor layer P3 disposed on a side of the base substrate P1, the first metal layer P4 disposed on a side of the semiconductor layer P3 facing away from the base substrate P1, the second metal layer P5 disposed on a side of the first metal layer P4 facing away from the base substrate P1, and the display layers (P7, P8, and P9) disposed on a side of the second metal layer P5 facing away from the base substrate P1. The semiconductor layer P3 includes the active layer M5g of the reset transistor M5. The first metal layer P4 includes the gate of the reset transistor M5. Along a direction perpendicular to the plane in which the base substrate P5 is located, the position where the active layer of the reset transistor M5 overlaps the gate of the reset transistor M5 is the channel region of the reset transistor M5. The second metal layer P5 includes the fifth signal lines 25 (Ref′). The first pole of the reset transistor M5 is electrically connected to a fifth signal line 25 (Ref′) through a tenth via hole H91. The display layers (P7, P8, and P9) include the light-emitting elements 40. The second pole of the reset transistor M5 is electrically connected to a light-emitting element 40 through the fourth via hole H4. In the active layer of the reset transistor M5, the region from the channel region M5g of the reset transistor M5 to the region M5d of a ninth via hole H92 electrically connected to the reset transistor M5 and the region from the channel region M5g of the reset transistor M5 to a region M5s of the fourth via hole H4 electrically connected to the reset transistor M5 are non-channel regions of the reset transistor M5. The ratio Sq of an area covered by the non-channel regions (M5s and M5d) of the reset transistor M5 to an area covered by the channel region M5g of the reset transistor M5 satisfies that 1.5≤Sq≤2.

Specifically, in the first metal layer P5 where the gate of the reset transistor M5 is located, only the gate of the reset transistor M5 is retained. The first line segment 211 (Scan3) electrically connected to the reset transistor M5 further serves as a portion 302 of a shielding unit 30 so that the structure on a side of the gate of the reset transistor M5 is disposed between gates of two adjacent reset transistors M5. In this case, the size of the active layer of the reset transistor M5 is reduced along the column direction Y of the pixel driving circuits 10 so that the area ratio of the non-channel regions (M5s and M5d) of the reset transistor M5 to the channel region M5g of the reset transistor M5 is reduced to the range of 1.5 to 2. Compared with the related art, the size of the active layer of the reset transistor M5 is relatively reduced by 30% to 60% along the column direction Y of the pixel driving circuits 10. In this manner, the arrangement in which at least part of the shielding unit 30 further serves as the reset signal line Ref′ electrically connected to the reset transistor M5 helps reduce the size of the reset transistor M5. Accordingly, the area of regions where the pixel driving circuits 10 are located is reduced, thus increasing the number of the pixel driving circuits 10 disposed in the display panel, contributing to the high resolution of the display panel, and meeting the requirements of display in a high light-transmitting region.

It is to be noted that FIGS. 31 and 32 are only exemplary drawings of embodiments of the present disclosure. FIGS. 31 and 32 only illustrate that the first pole of the reset transistor M5 is electrically connected to a fifth signal line 25 (ref′) through a third lap joint structure P603, as an example. In this case, the first pole of the reset transistor M5 may be electrically connected to the third lap joint structure P603 through the ninth via hole H92, and then the third lap joint structure P603 is electrically connected to the fifth signal line 25 (ref′) through a tenth via hole H91.

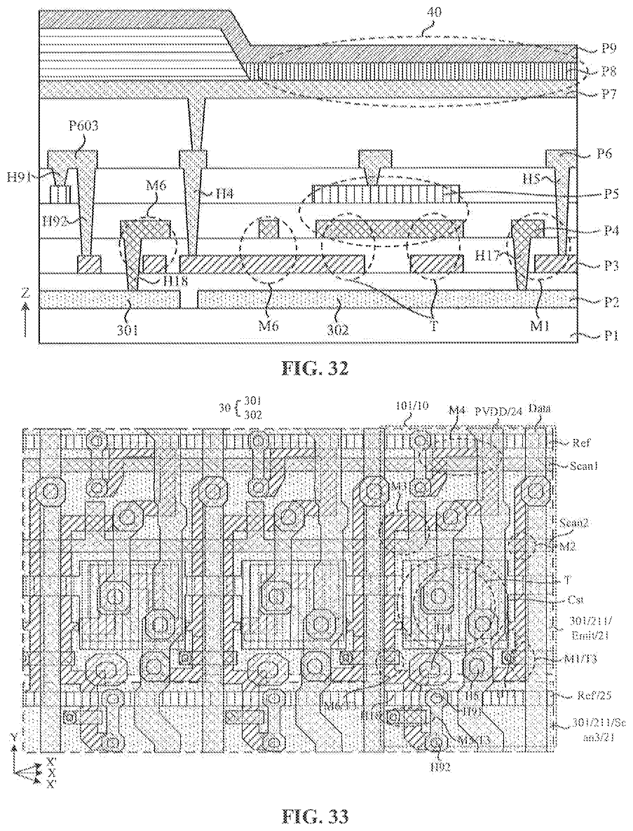

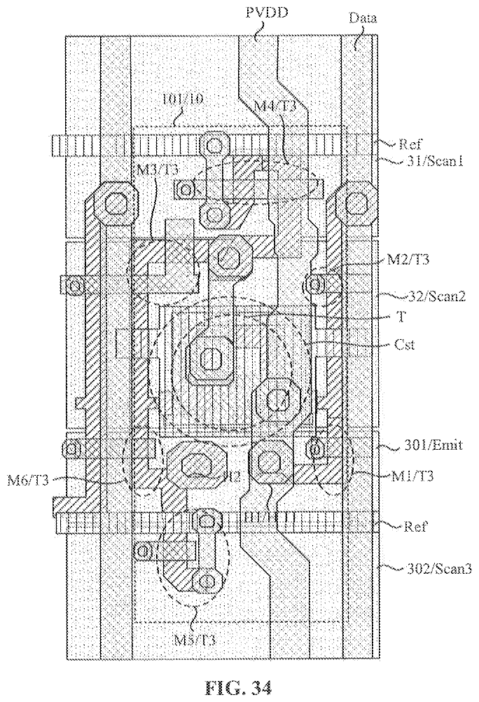

It is to be understood that FIG. 31 only illustrates that the ninth via hole H92 and the tenth via hole H91 are both disposed on the same side of the fifth signal line 25 (ref′), as an example. In embodiments of the present disclosure, the ninth via hole H92 and the tenth via hole H91 may further be disposed on two opposite sides of the fifth signal line 25 (ref′) (as shown in FIG. 33).

It is to be noted that in embodiments of the present disclosure, at least one third transistor T3 may only include the first light-emitting control transistor M1 and the second light-emitting control transistor M6, may only include the reset transistor M5, or may only include the first light-emitting control transistor M1, the second light-emitting control transistor M6, and the reset transistor M5. Alternatively, each transistor needed to be electrically connected to scanning signal lines among all the transistors in the first-type pixel driving circuits is a third transistor (as shown in FIG. 24). This is not specifically limited in embodiments of the present disclosure under the premise of reducing the area of regions where the first-type pixel driving circuits are located.

Additionally, in embodiments of the present disclosure, all the pixel driving circuits in the display panel may be first-type pixel driving circuits. In this case, compared with the related art, the area of regions where the first-type pixel driving circuits and the signal lines electrically connected to the first-type pixel driving circuits are located is reduced, thus increasing the number of the pixel driving circuits in the display panel and enhancing the resolution of the display panel. Moreover, when the display panel includes a high light-transmitting area, the size of the first-type pixel driving circuits is reduced and the area to be shielded is reduced. That is, the region to be provided with a shielding unit is reduced and the light-transmitting area of the high light-transmitting region is increased, thus meeting the requirements of light transmission and display in the high light-transmitting region. Alternatively, in the display panel, only part of the pixel driving circuits are first-type pixel driving circuits, which can also enhance the high resolution of the display panel and meet the requirements of light transmission and display in the high light-transmitting region.

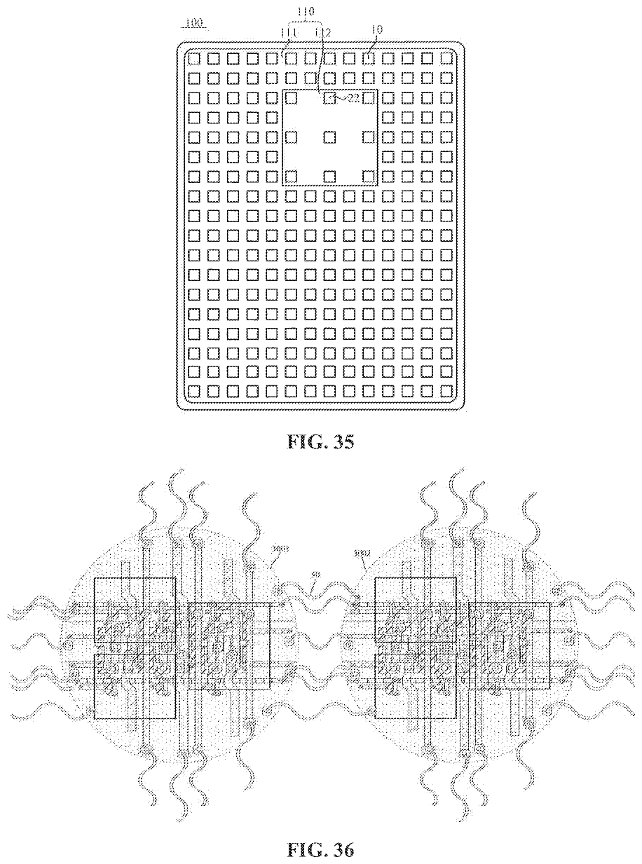

For example, FIG. 35 is a structure diagram of a display panel according to an embodiment of the present disclosure. As shown in FIG. 35, the display panel 100 includes a display region 110. The pixel driving circuits 10 are disposed in the display region 110. The display region 110 includes an optical element region 112 and a first display region 111 surrounding the optical element region 112. The pixel driving circuits 10 disposed in the optical element region 112 are electrically connected to the first line segments 211. With this arrangement, the pixel driving circuits 10 in the optical element region 112 have a relatively small size, thus increasing the light-transmitting area in the optical element region and meeting the requirements of light transmission and display in the optical element region 112.

In an embodiment, FIG. 36 is a top view illustrating part of a display panel according to another embodiment of the present disclosure. As shown in FIG. 36, the shielding unit include a plurality of shielding sub-units (3001, 3002). Along a direction perpendicular to the plane in which the base substrate is located, each shielding sub-unit (3001, 3002) overlaps at least one pixel driving circuit. In this case, the vertical projection of each shielding sub-unit (3001, 3002) on the base substrate is a first projection. An edge of the first projection is arcuate to avoid diffraction when light passes through the gap between two adjacent shielding sub-units, thus enhancing the display effect of the display panel. Moreover, when the display panel includes a high light-transmitting region and the high light-transmitting region is configured to dispose an optical sensor, the arrangement in which the projection of a shielding sub-unit in the high light-transmitting region is arcuate, the accuracy for the optical sensor collecting optical signals is improved.

In an embodiment, with further reference to FIG. 36, when the shielding unit include a plurality of shielding sub-units (3001, 3002), two adjacent shielding sub-units (3001 and 3002) may be connected through a connection line 50. The connection line may be transparent. In this case, the display panel further includes a transparent conductive layer disposed on a side of the base substrate. The transparent conductive layer includes a plurality of connection lines 50 to connect different shielding sub-units. The transparent conductive layer may be an indium tin oxide layer in the anode layer of the light-emitting elements. This arrangement enables light to transmit sufficiently in the region between two adjacent shielding sub-units (3001 and 3002), and a light-transmitting area would not be reduced due to disposing the connection lines.

It is to be noted that each connection line connecting two shielding sub-units (3001 and 3002) may also be a non-transparent connection line. In this case, each connection line may be curve to avoid diffraction when light passes through regions between the connection lines.

Based on the same inventive concept, embodiments of the present disclosure further provide a display device. The display device includes the display panel provided in embodiments of the present disclosure, so the display device has the technical features of the display panel provided in embodiments of the present disclosure and can achieve the beneficial effects of the display panel provided in embodiments of the present disclosure. Similarities may be referred to the preceding description of the display panel provided in embodiments of the present disclosure and are not repeated herein.

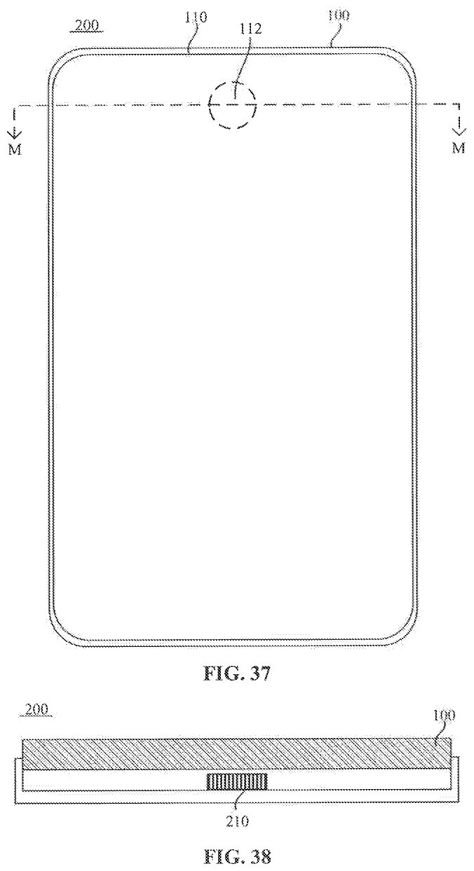

In an embodiment, FIG. 37 is a structure diagram of a display device according to an embodiment of the present disclosure. FIG. 38 is a section view taken along section M-M of FIG. 37. Referring to FIGS. 37 and 38, a display device 200 includes the display panel 100 and an optical sensor 210. A display region 110 of the display panel 100 includes an optical element region 112. The optical element region 112 is configured to dispose the optical sensor 210.

It is to be understood that the display device provided in embodiments of the present disclosure may be a mobile phone, a tablet computer, a smart wearable device (such as a smart watch), or other display device having the function of collecting optical signals and known to those skilled in the art, which is not limited in embodiments of the present disclosure.

It is to be noted that the preceding are only preferred embodiments of the present disclosure and the technical principles used therein. It is to be understood by those skilled in the art that the present disclosure is not limited to the embodiments described herein. For those skilled in the art, various apparent modifications, adaptations, combinations, and substitutions can be made without departing from the scope of the present disclosure. Therefore, while the present disclosure has been described in detail via the preceding embodiments, the present disclosure is not limited to the preceding embodiments and may include more equivalent embodiments without departing from the inventive concept of the present disclosure. The scope of the present disclosure is determined by the scope of the appended claims.

What is claimed is:

1. A display panel, comprising:
a plurality of pixel driving circuits disposed in an array, a plurality of first signal lines, and a shielding unit, wherein the plurality of pixel driving circuits are electrically connected to the plurality of first signal lines; and
a base substrate, wherein the plurality of pixel driving circuits, the plurality of first signal lines, and the shielding unit are all disposed on a side of the base substrate, and along a direction perpendicular to a plane in which the base substrate is located, at least part of the plurality of pixel driving circuits overlap the shielding unit;
wherein each of the plurality of first signal lines comprises a first line segment, and the first line segment is at least part of the shielding unit.

2. The display panel of claim 1, wherein a pixel driving circuit of the plurality of pixel driving circuits comprises at least one first transistor; and
wherein the pixel driving circuit electrically connected to the first line segment of the one first signal line refers to a first-type pixel driving circuit, a first pole of a first transistor of the at least one first transistor in the first-type pixel driving circuit is electrically connected to the first line segment through a first via hole, and the first pole of the first transistor is a source or a drain.

3. The display panel of claim 2, further comprising a plurality of second signal lines, wherein the pixel driving circuit further comprises a second transistor, a first pole of the second transistor is electrically connected to a second signal line of the plurality of second signal lines, and second transistors of the at least part of the plurality of pixel driving circuits disposed in a same column share a same second signal line of the plurality of second signal lines; and
wherein along a row direction of the plurality of pixel driving circuits, a distance between two second signal lines that are respectively electrically connected to two adjacent first-type pixel driving circuits in a same row is L1, and a width of the second signal line is L2, and wherein L1 and L2 satisfy 6≤L1/L2≤8.

4. The display panel of claim 2, further comprising a plurality of light-emitting elements disposed in an array;
wherein the at least one first transistor comprises a first light-emitting control transistor, the pixel driving circuit further comprises a second light-emitting control transistor and a driving transistor, wherein a second pole of the first light-emitting control transistor is electrically connected to a first pole of the driving transistor, a first pole of the second light-emitting control transistor is electrically connected to a second pole of the driving transistor, wherein a second pole of the second light-emitting control transistor is electrically connected to an anode of a light-emitting element of the plurality of light-emitting elements through a second via hole, and wherein in a case where the first pole is a source, the second pole is a drain, or, in a case where the first pole is a drain, the second pole is a source; and
wherein along a first direction, the first via hole electrically connected to the first light-emitting control transistor overlaps the second via hole, and wherein the first direction is parallel to the plane in which the base substrate is located, and a first included angle is disposed between the first direction and a column direction of the plurality of pixel driving circuits.

5. The display panel of claim 2, wherein the shielding unit comprise a plurality of shielding sub-units, and along the direction perpendicular to the plane in which the base substrate is located, each of the plurality of shielding sub-units overlaps N pixel driving circuits of the plurality of pixel driving circuits; and
wherein the pixel driving circuit further comprises a storage capacitor; among the plurality of pixel driving circuits, first plates of storage capacitors of the N pixel driving circuits overlapping a same shielding sub-unit are an integral structure; and among the plurality of first-type pixel driving circuits, the first plates of the storage capacitors being the integral structure are electrically connected to a same first line segment through M third via holes, wherein M<N, and M and N are both positive integers.

6. The display panel of claim 2, wherein the at least one first transistor comprises a data writing transistor, the pixel driving circuit further comprises a driving transistor, and the data writing transistor is configured to write data signals transmitted by the plurality of first signal lines into a gate of the driving transistor; and
wherein two adjacent first-type pixel driving circuits disposed sequentially along a row direction of the plurality of pixel driving circuits are a first pixel driving circuit and a second pixel driving circuit respectively, and along a first direction, the first via hole electrically connected to the data writing transistor in the first pixel driving circuit overlaps an active layer of the driving transistor in the second pixel driving circuit, wherein the first direction is parallel to the plane in which the base substrate is located, and a first included angle is disposed between the first direction and a column direction of the plurality of pixel driving circuits.

7. The display panel of claim 2, comprising:
a semiconductor layer disposed on a side of the base substrate, wherein the semiconductor layer comprises an active layer of the at least one first transistor; and
a first metal layer disposed on a side of the semiconductor layer facing away from the base substrate, wherein the first metal layer comprises a plurality of third signal lines; along the direction perpendicular to the plane in which the base substrate is located, a position where the plurality of third signal lines overlaps the active layer of the at least one first transistor is a gate of the at least one first transistor; and first transistors in at least part of the plurality of pixel driving circuits disposed in a same row share a third signal line of the plurality of third signal lines and a second signal line of the plurality of second signal lines.

8. The display panel of claim 7, wherein the pixel driving circuit further comprises a storage capacitor, the at least one first transistor comprises an initialization transistor, the initialization transistor and the storage capacitor are disposed sequentially along a column direction of the plurality of pixel driving circuits; the first metal layer comprises a second plate of the storage capacitor, and a second pole of the initialization transistor and the second plate of the storage capacitor are electrically connected at a first node, wherein in a case where the first pole is a source, the second pole is a drain, or in a case where the first pole is a drain, the second pole is a source; and
wherein the display panel further comprises:
a second metal layer disposed on a side of the first metal layer facing away from the base substrate, wherein the second metal layer comprises a first plate of the storage capacitor; and
a third metal layer disposed on a side of the second metal layer facing away from the base substrate, wherein the third metal layer comprises a plurality of fourth signal lines, the first plate of the storage capacitor is electrically connected to a fourth signal line of the plurality of fourth signal lines through a third via hole, and storage capacitors in at least part of the plurality of pixel driving circuits disposed in a same column share a fourth signal line of the plurality of fourth signal lines; and
wherein the display panel further comprises a first conductive layer, wherein the first conductive layer comprises the first line segment, the first conductive layer is disposed between the base substrate and the semiconductor layer, or between the third metal layer and the semiconductor layer,
wherein the first via hole electrically connected to the initialization transistor is disposed on a side of the plurality of third signal lines facing the storage capacitor.

9. The display panel of claim 7, wherein the pixel driving circuit further comprises a storage capacitor, the at least one first transistor comprises an initialization transistor, the initialization transistor and the storage capacitor are disposed sequentially along a column direction of the plurality of pixel driving circuits; the first metal layer comprises a second plate of the storage capacitor, and a second pole of the initialization transistor and the second plate of the storage capacitor are electrically connected at a first node, wherein in a case where the first pole is a source, the second pole is a drain, or in a case where the first pole is a drain, the second pole is a source;
wherein the display panel further comprises:
a second metal layer disposed on a side of the first metal layer facing away from the base substrate, wherein the second metal layer comprises a first plate of the storage capacitor; and
a third metal layer disposed on a side of the second metal layer facing away from the base substrate, wherein the third metal layer comprises a plurality of fourth signal lines and a plurality of first lap joint structures, the first plate of the storage capacitor is electrically connected to a fourth signal line of the plurality of fourth signal lines through a third via hole, and storage capacitors in at least part of the plurality of pixel driving circuits disposed in a same column share a fourth signal line of the plurality of fourth signal lines; and
a first conductive layer disposed on a side of the third metal layer facing away from the base substrate and comprising the first line segment;
wherein the first via hole electrically connected to the initialization transistor comprises a first sub-via and a second sub-via, a first pole of the initialization transistor is electrically connected to a first lap joint structure of the plurality of first lap joint structures through the first sub-via, and the first lap joint structure is electrically connected to the first line segment through the second sub-via, wherein the first sub-via is disposed on a side of the plurality of third signal lines facing the storage capacitor, and the second sub-via is disposed on a side of the plurality of third signal lines facing away from the storage capacitor.

10. The display panel of claim 7, further comprising: a plurality of light-emitting elements disposed in an array, wherein the at least one first transistor comprises a reset transistor, and a second pole of the reset transistor is electrically connected to an anode of an light-emitting element of the plurality of light-emitting elements through a fourth via hole, wherein in a case where the first pole is a source, the second pole is a drain, or in a case where the first pole is a drain, the second pole is a source; and
wherein along the direction perpendicular to the plane in which the base substrate is located, a position where an active layer of the reset transistor overlaps the plurality of third signal lines is a channel region of the reset transistor; in the active layer of the reset transistor, a region from the channel region of the reset transistor to a first via hole electrically connected to the reset transistor and a region from the channel region of the reset transistor to a fourth via hole electrically connected to the reset transistor are non-channel regions of the reset transistor; and a ratio Sq of an area of the non-channel regions of the reset transistor to an area of the channel region of the reset transistor satisfies 1.5≤Sq≤2.

11. The display panel of claim 7, further comprising:
a third metal layer disposed on a side of the first metal layer facing away from the base substrate, wherein the third metal layer comprises a plurality of fourth signal lines; and
a display layer disposed on a side of the third metal layer facing away from the base substrate, wherein the display layer comprises a plurality of light-emitting elements disposed in an array;
wherein the display panel further comprises a first conductive layer, wherein the first conductive layer comprises the first line segment, and the first conductive layer is disposed between the base substrate and the semiconductor layer, or between the third metal layer and the semiconductor layer,
wherein the at least one first transistor comprises a reset transistor; the pixel driving circuit further comprises light-emitting control transistors and a driving transistor; the driving transistor, the light-emitting control transistors, and the reset transistor are disposed sequentially along a column direction of the plurality of pixel driving circuits; the light-emitting control transistors comprise a first light-emitting control transistor and a second light-emitting control transistor; a first pole of the first light-emitting control transistor is electrically connected to a fourth signal line of the plurality of fourth signal lines through a fifth via hole, and a second pole of the first light-emitting control transistor is electrically connected to a first pole of the driving transistor; a first pole of the second light-emitting control transistor is electrically connected to a second pole of the driving transistor, the second light-emitting control transistor and the reset transistor are electrically connected at a second node, and the second light-emitting control transistor and the reset transistor are both electrically connected to an anode of a light-emitting element of the plurality of light-emitting elements through a fourth via hole at the second node, and wherein in a case where the first pole is a source, the second pole is a drain, or in a case where the first pole is a drain, the second pole is a source; and
wherein a first via hole electrically connected to the reset transistor is disposed on a side of the plurality of third signal lines facing away from the fourth via hole and the fifth via hole.

12. The display panel of claim 7, further comprising:
a third metal layer disposed on a side of the first metal layer facing away from the base substrate, wherein the third metal layer comprises a plurality of fourth signal lines and a plurality of second lap joint structures;
a display layer disposed on a side of the third metal layer facing away from the base substrate, wherein the display layers comprise a plurality of light-emitting elements disposed in an array; and
a first conductive layer disposed between the display layers and the third metal layer, wherein the first conductive layer comprises first line segments,
wherein the at least one first transistor comprises a reset transistor; the pixel driving circuit further comprises light-emitting control transistors and a driving transistor; the driving transistor, the light-emitting control transistors, and the reset transistor are disposed sequentially along a column direction of the plurality of pixel driving circuits; the light-emitting control transistors comprise a first light-emitting control transistor and a second light-emitting control transistor; a first pole of the first light-emitting control transistor is electrically connected to a fourth signal line of the plurality of fourth signal lines through a fifth via hole, and a second pole of the first light-emitting control transistor is electrically connected to a first pole of the driving transistor; a first pole of the second light-emitting control transistor is electrically connected to a second pole of the driving transistor, the second light-emitting control transistor and the reset transistor are electrically connected at a second node, and the second light-emitting control transistor and the reset transistor are both electrically connected to an anode of a light-emitting element of the plurality of light-emitting elements through a fourth via hole at the second node, wherein in a case where the first pole is a source, the second pole is a drain, or in a case where the first pole is a drain, the second pole is a source; and
wherein a first via hole electrically connected to the reset transistor comprises a third sub-via and a fourth sub-via, a first pole of the reset transistor is electrically connected to a second lap joint structure of the plurality of second lap joint structures through the third sub-via, and the second lap joint structure is electrically connected to the first line segment through the fourth sub-via, wherein the third sub-via is disposed on a side of the plurality of third signal lines facing away from the fourth sub-via, and along the direction perpendicular to the plane in which the base substrate is located, the fourth sub-via overlaps a region between the fourth via hole and the fifth via hole.

13. The display panel of claim 1, wherein a pixel driving circuit of the plurality of pixel driving circuits comprises at least one third transistor; and
wherein among the plurality of pixel driving circuits, a pixel driving circuit electrically connected to the first line segment of the first signal line refers to a first-type pixel driving circuit, a gate of a third transistor of the at least one third transistor in the first-type pixel driving circuit is electrically connected to the first line segment through a first via hole, and gates of any two third transistors in a same first-type pixel driving circuit are insulated from each other.

14. The display panel of claim 13, wherein the pixel driving circuit further comprises a driving transistor and an initialization transistor; the at least one third transistor comprises a data writing transistor and a threshold compensation transistor; the data writing transistor and the threshold compensation transistor are disposed sequentially along a row direction of the plurality of pixel driving circuits; and the initialization transistor, the threshold compensation transistor, and the driving transistor are disposed sequentially along a column direction of the plurality of the pixel driving circuits;
wherein a second pole of the data writing transistor is electrically connected to a first pole of the driving transistor; a first pole of the threshold compensation transistor is electrically connected to a second pole of the driving transistor; and a second pole of the initialization transistor, a second pole of the threshold compensation transistor, and a gate of the driving transistor are electrically connected at a first node, wherein in a case where the first pole is a source, the second pole is a drain, or in a case where the first pole is a drain, the second pole is a source; and
wherein data writing transistors and threshold compensation transistors in at least part of the plurality of pixel driving circuits disposed in a same row share a first signal line of the plurality of first signal lines, and in the first-type pixel driving circuit, a gate of the data writing transistor and a gate of the threshold compensation transistor are electrically connected to a same first line segment.

15. The display panel of claim 14, comprising:
a semiconductor layer disposed on a side of the base substrate, wherein the semiconductor layer comprises an active layer of the data writing transistor, an active layer of the threshold compensation transistor, an active layer of the initialization transistor, and an active layer of the driving transistor, wherein the active layer comprises a channel region and a first pole and a second pole that are disposed on two sides of the channel region; and
a first metal layer disposed on a side of the semiconductor layer facing away from the base substrate, wherein the first metal layer comprises a gate of the data writing transistor, a gate of the threshold compensation transistor, a gate of the initialization transistor, and a gate of the driving transistor; and along the direction perpendicular to the plane in which the base substrate is located, a position in the active layer where the active layer overlaps the gate is the channel region of the active layer,
wherein the first node comprises a first sub-section and a second sub-section, the first sub-section extends along the row direction of the plurality of pixel driving circuits and is configured to electrically connect the second pole of the threshold compensation transistor to the second pole of the initialization transistor, and the second sub-section extends along the column direction of the plurality of the pixel driving circuits and is configured to electrically connect the first sub-section to the gate of the driving transistor; and
wherein along the direction perpendicular to the plane in which the base substrate is located, the first sub-section and the second sub-section do not overlap each other.

16. The display panel of claim 15, wherein the active layer of the threshold compensation transistor comprises a first channel region and a second channel region;
wherein along a second direction, the second pole of the initialization transistor and the first sub-section overlap at least one of the first channel region and the second channel region, and wherein the second direction is parallel to the plane in which the base substrate is located, and a second included angle is disposed between the second direction and the row direction of the plurality of pixel driving circuits.

17. The display panel of claim 16, wherein the first sub-section and the second sub-section are both disposed in the semiconductor layer, one end of the second sub-section is electrically connected to the first sub-section, and an other end of the second sub-section is electrically connected to the gate of the driving transistor through a sixth via hole; and
wherein the second channel region is disposed on a side of the first channel region facing the driving transistor, and the first sub-section is disposed on a side of the first channel region facing the driving transistor.

18. The display panel of claim 16, further comprising:
a third metal layer disposed on a side of the first metal layer facing away from the base substrate, wherein the third metal layer comprises the second sub-section, the first sub-section is disposed in the semiconductor layer, one end of the second sub-section is electrically connected to the first sub-section through a seventh via hole, and an other end of the second sub-section is electrically connected to the gate of the driving transistor through an eighth via hole.

19. The display panel of claim 16, wherein the threshold compensation transistor comprises a first gate and a second gate, the first gate of the threshold compensation transistor overlaps the first channel region, the second gate of the threshold compensation transistor overlaps the second channel region, and the first gate of the threshold compensation transistor and the second gate of the threshold compensation transistor are insulated from each other, and
Wherein along the second direction, the second gate of the threshold compensation transistor overlaps the active layer of the driving transistor.

20. The display panel of claim 13, further comprising a plurality of light-emitting elements disposed in an array and a plurality of fourth signal lines, wherein
the pixel driving circuit further comprises a driving transistor, the at least one third transistor comprises a first light-emitting control transistor and a second light-emitting control transistor disposed sequentially along a row direction of the plurality of pixel driving circuits, a first pole of the first light-emitting control transistor is electrically connected to a fourth signal line of the plurality of fourth signal lines through a fifth via hole, first light-emitting control transistors in at least part of the plurality of pixel driving circuits disposed in a same column share the fourth signal line, a second pole of the first light-emitting control transistor is electrically connected to a first pole of the driving transistor, a first pole of the second light-emitting control transistor is electrically connected to a second pole of the driving transistor, and the second light-emitting control transistor is electrically connected to an anode of the light-emitting element through a fourth via hole, wherein in a case where the first pole is a source, the second pole is a drain, or in a case where the first pole is a drain, the second pole is a source, and
along a second direction, the fifth via hole and the fourth via hole overlap at least one of a gate of the first light-emitting control transistor and a gate of the second light-emitting control transistor, wherein the second direction is parallel to the plane in which the base substrate is located, and a second included angle is disposed between the second direction and the row direction of the plurality of pixel driving circuits.

21. The display panel of claim 13, further comprising a plurality of light-emitting elements disposed in an array and a plurality of fifth signal lines, wherein the at least one third transistor comprises a reset transistor, wherein
a first pole of the reset transistor is electrically connected to a fifth signal line of the plurality of fifth signal lines, reset transistors in at least part of the plurality of pixel driving circuits in a same row among the plurality of pixel driving circuits share the fifth signal line, and a second pole of the reset transistor is electrically connected to an anode of a light-emitting element of the plurality of light-emitting elements, wherein in a case where the first pole is a source, the second pole is a drain, or in a case where the first pole is a drain, the second pole is a source.

22. The display panel of claim 21, further comprising:
a semiconductor layer disposed on a side of the base substrate, wherein the semiconductor layer comprises an active layer of the reset transistor;
a first metal layer disposed on a side of the semiconductor layer facing away from the base substrate, wherein the first metal layer comprises a gate of the reset transistor, and along the direction perpendicular to the plane in which the base substrate is located, a position where the active layer of the reset transistor overlaps the gate of the reset transistor is a channel region of the reset transistor;
a second metal layer disposed on a side of the first metal layer facing away from the base substrate, wherein the second metal layer comprises the plurality of fifth signal lines, and the first pole of the reset transistor is electrically connected to the fifth signal line through a ninth via hole; and
a display layer disposed on a side of the second metal layer facing away from the base substrate, wherein the display layer comprises the plurality of light-emitting elements, and the second pole of the reset transistor is electrically connected to the light-emitting element through a fourth via hole,
wherein in the active layer of the reset transistor, a region from the channel region of the reset transistor to the ninth via hole electrically connected to the reset transistor, and a region from the channel region of the reset transistor to the fourth via hole electrically connected to the reset transistor are non-channel regions of the reset transistor; and a ratio Sq of an area of the non-channel regions of the reset transistor to an area of the channel region of the reset transistor satisfies 1.5≤Sq≤2.

23. The display panel of claim 1, wherein the shielding unit comprise a plurality of shielding sub-units, and along the direction perpendicular to the plane in which the base substrate is located, each of the plurality of shielding sub-units overlaps at least one pixel driving circuit of the plurality of pixel driving circuits.

24. The display panel of claim 23, further comprising:
a first conductive layer disposed on a side of the base substrate, wherein each of the plurality of shielding sub-units comprises at least one first shielding structure, the first conductive layer comprises the at least one first shielding structure, and the at least one first shielding structure each further serves as the first line segment, and wherein
the plurality of first signal lines are configured to transmit fixed voltage signals, and first line segments electrically connected to pixel driving circuits covered by a same shielding sub-unit among the plurality of pixel driving circuits are an integral structure.

25. The display panel of claim 23, further comprising:
a first conductive layer disposed on a side of the base substrate, wherein each of the plurality of shielding sub-units comprises at least one first shielding structure, the first conductive layer comprises the at least one first shielding structure, and the at least one first shielding structure each further serves as the first line segment, and wherein
the plurality of first signal lines are configured to transmit variable voltage signals, and any two first line segments are insulated from each other.

26. The display panel of claim 25, further comprising:
a second metal layer, wherein the each of the plurality of shielding sub-units further comprises at least one second shielding structure, the second metal layer comprises the at least one second shielding structure, and along the direction perpendicular to the plane in which the base substrate is located, the at least one second shielding structure overlaps a gap among the at least one first shielding structure, and wherein
the pixel driving circuit comprises a storage capacitor, and the second metal layer further comprises a first plate of the storage capacitor.

27. The display panel of claim 25, further comprising:
a plurality of light-emitting elements disposed in an array; and
an anode metal layer disposed on a side of the base substrate, wherein the each of the plurality of shielding sub-units further comprises at least one third lap joint structure, and the anode metal layer comprises the at least one third lap joint structure and anodes of the plurality of light-emitting elements,
wherein along the direction perpendicular to the plane in which the base substrate is located, the at least one third shielding structure overlaps a gap among the at least one first shielding structure.

28. The display panel of claim 23, wherein a vertical projection of each of the plurality of shielding sub-units on the base substrate is a first projection, and an edge of the first projection is arcuate.

29. The display panel of claim 23, further comprising:
a transparent conductive layer disposed on a side of the base substrate, wherein the transparent conductive layer comprises a plurality of connection lines configured to connect the plurality of pixel driving circuits overlapping different shielding sub-units of the plurality of shielding sub-units.

30. The display panel of claim 23, further comprising a plurality of connection lines configured to connect the plurality of pixel driving circuits overlapping different shielding sub-units of the plurality of shielding sub-units, and the plurality of connection lines each is a curve.

31. The display panel of claim 1, further comprising a display region, wherein the plurality of pixel driving circuits are disposed in the display region, and wherein
the display region comprises an optical element region and a first display region surrounding the optical element region, and the plurality of pixel driving circuits disposed in the optical element region are electrically connected to the first line segment.

32. A display device, comprising a display panel, wherein the display panel comprises:
a plurality of pixel driving circuits disposed in an array, a plurality of first signal lines, and a shielding unit, wherein the plurality of pixel driving circuits are electrically connected to the plurality of first signal lines; and
a base substrate, wherein the plurality of pixel driving circuits, the plurality of first signal lines, and the shielding unit are all disposed on a side of the base substrate, and along a direction perpendicular to a plane in which the base substrate is located, at least part of the plurality of pixel driving circuits overlap the shielding unit,
wherein each of the plurality of first signal lines comprises a first line segment, and the first line segment is at least part of the shielding unit.

33. The display device of claim 32, further comprising an optical sensor, wherein
the display panel further comprises a display region, the display region comprises an optical element region, and the optical sensor is disposed in the optical element region.
